(19) United States
(12) Patent Application Publication
(10) Pub. No.: US 2005/0231396 A1
(43) Pub. Date: Oct. 20, 2005

(54) Audio compression

(75) Inventor: Chris Dunn, London (GB)

Correspondence Address: BARNES & THORNBURG, 750-17TH STREET NW, SUITE 900, WASHINGTON, DC, 20006, US

(73) Assignee: Scala Technology Limited, London NW5 2HP (GB)

(21) Appl. No.: 10/514,298

(22) PCT Filed: May 12, 2003
(86) PCT No.: PCT/GB03/02031

§ 371 Date: Apr. 26, 2005

(30) Foreign Application Priority Data
May 10, 2002 (GB) 0210704.3

(51) Int. Cl. H03M 7/00

(52) U.S. Cl. 341/50

(57) ABSTRACT

A method of scalable audio compression includes bitplane coding of frequency-domain transform coefficients, where newly-significant coefficient locations within the current bitplane are identified using runlength codes. Reordering coefficients prior to bitplane coding such that same-frequency coefficients are clustered together has the effect of increasing coding efficiency. The invention is applicable to both full-bandwidth and layered bitplane coding.

### FIELD OF THE INVENTION

This invention relates generally to the field of audio compression, in particular to efficient methods for encoding and scalably decoding audio signals.

### BACKGROUND

Audio coding algorithms with bitrate scalability allow an encoder to transmit or store compressed data at a relatively high bitrate and decoders to successfully decode a lower-rate datastream contained within the high-rate code. For example, an encoder might transmit at 128 kbit/s while a decoder would decode at 32, 64, 96 or 128 kbit/s according to channel bandwidth, decoder complexity and quality requirements. Scalability is becoming an important aspect of low bitrate audio coding, particularly for multimedia applications where a range of coding bitrates may be required, or where bitrate fluctuates. Fine-grain scalability, where useful increases in coding quality can be achieved with small increments in bitrate, is particularly desirable.

The growth of the internet has created a demand for high-quality streamed audio content. Audio coding with fine-grain bitrate scalability allows uninterrupted service in the presence of channel congestion, achieves real-time streaming with low buffer delay, and yields the most efficient use of available channel bandwidth. Scalability is also useful in archiving, where a program item may be coded at the highest bitrate required and stored as a single file, rather than storing many coded versions across the range of required bitrates. As well as the saving in overall storage requirement, bitrate scalability can reduce the cumulative reduction in coding quality that can occur due to recoding. Scalable audio coding has further applications in mobile multimedia communication, digital audio broadcasting, and remote personal media storage.

While fine-grain bitrate scalability can be extremely useful, it is important that it is achieved without significant coding efficiency penalty relative to fixed bitrate systems, and with low computational complexity.

Audio compression algorithms typically include some form of transform coding where the time-domain audio signal is split into a series of frames, each of which is then transformed to the frequency domain before quantisation, entropy coding and frame packing to a coded datastream. A psychoacoustic model determines a target noise shaping profile which is used to allocate bits to the transform coefficients such that quantisation errors for each frame are least audible to the human ear. In a conventional fixed-bitrate encoder the bit allocation is typically achieved with a recursive algorithm that attempts to meet the noise-shaping requirement within the bitrate constraint (see J. D. Johnston, “Transform Coding of Audio Signals Using Perceptual Noise Criteria,” IEEE J. Select Areas in Communications, vol. 6, pp. 314-323 (1988 February)). The final bit allocation computed is used to quantise transform coefficients and also included as side information within the datastream for use at the decoder. Datastream decoding is restricted to the bitrate of the encoded signal.

A common approach to achieving scalability is the ‘error-feedforward’ arrangement, (for example J. Herre et al., “The Integrated Filterbank Based Scalable MPEG-4 Audio Coder,” presented at the 105^{th} Convention of the Audio Engineering Society, San Francisco, 1998 (preprint 4810)), where a core coder produces the lowest embedded bit rate and subsequent layers progressively reduce the error due to the core. However, a significant amount of side information is associated with each layer which can reduce coding efficiency, and the number of possible decoding rates is limited to the number of layers.

An alternative approach to achieving scalability is ordered bitplane coding of transform coefficients, where in each frame coefficient bitplanes are coded in order of significance, beginning with the most significant bits (MSB's) and progressing to the least-significant bits (LSB's). This results in fully-embedded coding where the datastream at a certain rate contains all lower-rate codes, and exhibits fine-grain scalability in contrast to the coarse granularity offered by error-feedforward systems. A lower bitrate version of a coded signal can be simply constructed by discarding the later bits of each coded frame. Bitplane coding can also yield a significant increase in encoding speed since ordered bitplanes are coded sequentially until the bit allocation for the frame is met, as opposed to the recursive bit allocation search executed in fixed-rate coding.

Ordered bitplane coding is used in the Bit-Sliced Arithmetic Coding (BSAC) system (S. H. Park et al., “Multi-Layer Bit-Sliced Bit Rate Scalable Audio Coding,” presented at the 103^{rd} Convention of the Audio Engineering Society, New York, September 1997 (preprint 4520), and S. H. Park, “Scalable Audio Coding/Decoding Method and Apparatus,” EP 0884850 (1998 December). However the BSAC coder requires the use of arithmetic coding which can increase computational complexity.

An object of certain aspects of this invention is to provide a method and apparatus for efficiently coding audio signals with fine-grain bitrate scalability.

### SUMMARY OF THE INVENTION

According to one aspect of the present invention there is provided a method for encoding audio signals to a datastream, comprising the steps of:
(a) reordering frequency-domain coefficients representing the audio signal to a coefficient list, where the list order preserves the frequency order of coefficients and groups together coefficients with the same frequency index;
(b) quantising the coefficients and coding bits of equal significance together in bitplanes, where bitplanes are coded in order of significance beginning with the most significant bitplane, and coding of one or more bitplanes comprises the steps of:
   (i) locating newly-significant coefficients with most-significant magnitude bit (MSB) positions within the current bitplane, by runlength coding positions of coefficient list entries whose magnitudes equal or exceed a predetermined threshold level corresponding to the current bitplane;
   (ii) coding the signs of said newly-significant coefficients;
   (iii) removing said newly-significant coefficients from the coefficient list.
(c) outputting coded bitplane data to the datastream.

Bitplanes may be coded individually, or it may be preferable to group one or more bitplanes together and code bitplanes in groups.

In certain applications in which audio signals are divided into frames, which in turn contain one or more blocks, reordering may advantageously comprise, for each frame, a data independent mapping such that coefficients with the same frequency index but from different transform blocks are clustered together within the coefficient list. The length of the frames and the number of blocks may vary according to characteristics of the input signal.

One example of such an application is where modified-discrete cosine transforms (MDCTs) are used. Here blocks of samples within the frame are windowed and transformed to the frequency domain. The MDCT uses 50%-overlapping windows, such that with a frame length of K time-domain input samples and an MDCT window length of 2M, the number of blocks of frequency-domain coefficients output for each frame B=K/M. Each output block contains M unique coefficients ranging from dc to half the sampling frequency.

Alternative embodiments may use the wavelet packet (WP) transform, which can be arranged to achieve a nonuniform decomposition where time and frequency resolution vary as a function of frequency. It is also possible to obtain a nonuniform decomposition with an MDCT-based system by combining high-frequency coefficients. In such embodiments a coefficient reordering process similar to the uniform transform case is performed prior to bitplane coding of nonuniform transform coefficients, where all coefficients with the same subband frequency index are grouped together within the coefficient list.

In many applications, audio data to be coded will be such that frequency domain coefficients with the same frequency index will tend to be of similar magnitude. Where this is the case, the reordering process has the advantageous effect of clustering together coefficients with similar magnitudes. This tends to improve coding efficiency when the coefficient list is then bitplane coded.

Preferably, adaptive runlength coding is used. A preferred coding scheme uses Golomb codes, including a Golomb parameter. More preferably adaptive Golomb codes are used, where the Golomb parameter is adaptive. The Golomb parameter may be set for each bitplane or group of bitplanes, or may adapt according to previously coded data.

The datastream may comprise a base layer and a number of enhancement layers having predetermined bandwidth limits, and may be further characterised in that the coefficients corresponding to the base layer having a bandwidth limit are quantised and coded until a bit allocation is reached, and then the coefficients corresponding to an enhancement layer having a bandwidth limit are quantised and coded until a bit allocation is reached, the quantisation and coding being repeated until all layers have been coded.

According to another aspect of the present invention, there is provided a method for decoding a datastream representing an audio signal, comprising the steps of:
(a) initialising entries in a coefficient list to zero, where the list order preserves the frequency order of coefficients and groups together coefficients with the same frequency index;
(b) decoding bitplane data from the datastream in order of significance beginning with the most significant bitplane, where bitplane data corresponds to quantised coefficient bits of equal significance, and decoding of one or more bitplanes comprises the steps of:
   (i) decoding runlength codes to locate newly-significant coefficient list entries which have most-significant magnitude bit (MSB) positions within the current bitplane;
   (ii) setting magnitudes of said newly-significant coefficient list entries to a predetermined threshold level corresponding to the current bitplane;
   (iii) decoding the signs of said newly-significant coefficient list entries;
   (iv) removing said newly-significant entries from the coefficient list.
(c) reordering significant coefficients removed from the coefficient list to a set of frequency-domain output coefficients.

According to a further aspect of the present invention, there is provided a method for encoding audio signals to a layered datastream having a base layer and a predetermined number of enhancement layers, comprising the steps of:
(a) reordering frequency-domain coefficients representing an audio signal to a coefficient list, where the list order preserves the frequency order of coefficients and groups together coefficients with the same frequency index;
(b) quantising and coding coefficients corresponding to the base layer with a predetermined bandwidth limit, until a predetermined bit allocation for the base layer is reached;
(c) quantising and coding coefficients corresponding to the next enhancement layer with a predetermined bandwidth limit, until a predetermined bit allocation for the enhancement layer is reached;
(d) sequentially performing step (c) until all layers have been coded, wherein steps (b), (c) and (d) each includes coding quantised coefficient bits of equal significance together in bitplanes, where bitplanes are coded in order of significance beginning with the most significant bitplane, and coding of one or more bitplanes comprises the steps of:
   (i) locating newly-significant coefficients with most-significant magnitude bit (MSB) positions within the current bitplane, by runlength coding positions of coefficient list entries whose magnitudes equal or exceed a predetermined threshold level corresponding to the current bitplane;
   (ii) coding the signs of said newly-significant coefficients;
   (iii) removing said newly-significant coefficients from the coefficient list.
(e) outputting coded layer data to the datastream.

It may be the case that bitplanes in some layers contain no new significant coefficients. This may particularly be the case for more significant bitplanes in higher layers, especially after the reordering process. In certain embodiments therefore, prior to coding a bitplane a flag may be output to indicate whether the coefficient list contains any newly-significant coefficients within the bitplane up to the bandwidth limit of the layer. The flag may for example comprise a single bit. For bitplanes with no new significant entries, the flag can simply be set to indicate this, and that bitplane need not be coded for newly-significant coefficients, thus improving coding efficiency. Bitplane significance flags may advantageously be used for coding only selected layers, or selected bitplanes within selected layers. In a preferred embodiment significance flags are used for all layers except the base layer.

This feature may be independently provided and therefore, according to a further aspect of the invention there is provided a method for use in the encoding of audio signals to a layered data stream using run length bitplane coding, wherein the location of newly-significant coefficients with most-significant magnitude bit (MSB) positions within the current bitplane are runlength coded, characterised in that runlength codes are preceded by a flag to indicate whether the coefficient list contains any newly-significant coefficients within the bandwidth limit of the current layer.

According to a further aspect of the present invention, there is provided a method for decoding audio signals from a layered datastream having a base layer and a predetermined number of enhancement layers, comprising the steps of:
(a) initialising entries in a coefficient list to zero, where the list order preserves the frequency order of coefficients and groups together coefficients with the same frequency index;
(b) decoding data from the datastream corresponding to the base layer with a predetermined bandwidth limit, until a predetermined bit allocation for the base layer is reached;
(c) decoding data from the datastream corresponding to the next enhancement layer with a predetermined bandwidth limit, until a predetermined bit allocation for the enhancement layer is reached;
(d) sequentially performing step (c) until all layers have been decoded, wherein steps (b), (c) and (d) each includes decoding bitplane data corresponding to quantised coefficient bits of equal significance, where bitplanes are decoded in order of significance beginning with the most-significant bitplane, and decoding of one or more bitplanes comprises the steps of:
   (i) decoding runlength codes to locate newly-significant coefficient list entries which have most-significant magnitude bit (MSB) positions within the current bitplane;
   (ii) setting said newly-significant coefficient list entries to a predetermined threshold level corresponding to the current bitplane;
   (iii) decoding the signs of said newly-significant coefficient list entries;
   (iv) removing said newly-significant entries from the coefficient list.
(e) reordering significant coefficients removed from the coefficient list to a set of frequency-domain output coefficients.

At lower bitrates, coefficients can only be recovered within a limited bandwidth range defined by the limits of the datastream layers. This can cause nonlinear artifacts in the time-domain output following frequency-to-time transformation if the final encoded layer is not decoded, due to the missing high frequency coefficients. In some applications it may be desirable for the decoding method to further comprise the step of transforming reconstructed output coefficients to a time-domain output signal and lowpass filtering the time-domain output signal. This can reduce the audibility of these artifacts. A lowpass filter response, defined by a filter cutoff frequency and transition bandwidth, will tradeoff bandwidth against artifact attenuation. Desirably the filter cutoff frequency should track the bandwidth limit of the last decoded layer. If the decoded bitrate changes from frame to frame, as may occur if the coded datastream is received over a variable-bandwidth channel link, an adaptive filter is preferably used in which the filter cutoff frequency is dependent on the coefficient bandwidth limit of the last decoded layer and which can adapt in time to variations in the decoded bandwidth limit.

This feature may be provided independently, and therefore, according to a further aspect of the present invention, there is provided a method for decoding audio signals from a layered datastream having a base layer and a predetermined number of enhancement layers, where decoding of each frame of coded data comprises the steps of:
(a) decoding data from the datastream and reconstructing output coefficients corresponding to the base layer with a predetermined bandwidth limit, until a predetermined bit allocation for the base layer is reached or all of the data for the frame has been decoded;
(b) decoding data from the datastream and reconstructing output coefficients corresponding to the next enhancement layer with a predetermined bandwidth limit, until a predetermined bit allocation for the enhancement layer is reached or all of the data for the frame has been decoded;
(c) sequentially performing step (b) until all layers have been decoded, or until all of the data for the frame has been decoded;
(d) transforming reconstructed output coefficients to a time-domain output signal;
(e) lowpass filtering the time-domain output signal, where the lowpass filter cutoff frequency is dependent on the bandwidth limit of the last layer decoded.

According to a further aspect of the present invention, there is provided an apparatus for encoding audio signals to a datastream, the apparatus comprising:
(a) reordering means for reordering frequency-domain coefficients representing an audio signal to a coefficient list, where the reordering means is configured to preserve the frequency order of coefficients within the list, and to grouping together coefficients with the same frequency index;
(b) bitplane coding means for quantising the coefficients and coding bits of equal significance together in bitplanes, where the bitplane coding means is configured to code bitplanes in order of significance beginning with the most-significant bitplane, and coding of one or more bitplanes comprises the steps of;
   (i) locating newly-significant coefficients with most-significant magnitude bit (MSB) positions within the current bitplane, by runlength coding positions of coefficient list entries whose magnitudes equal or exceed a predetermined threshold level corresponding to the current bitplane;
   (ii) coding the signs of said newly-significant coefficients;
   (iii) removing said newly-significant coefficients from the coefficient list.
(d) means for outputting coded bitplane data to the datastream.

According to a further aspect of the present invention, there is provided an apparatus for decoding a datastream representing an audio signal, the apparatus comprising:
(a) means for initialising entries in a coefficient list to zero, where the list order preserves the frequency order of coefficients and groups together coefficients with the same frequency index;
(b) bitplane decoding means for decoding bitplane data from the datastream in order of significance beginning with the most significant bitplane, where bitplane data corresponds to quantised coefficient bits of equal significance, and decoding of one or more bitplanes comprises the steps of:
   (i) decoding runlength codes to locate newly-significant coefficient list entries which have most-significant magnitude bit (MSB) positions within the current bitplane;
   (ii) setting magnitudes of said newly-significant coefficient list entries to a predetermined threshold level corresponding to the current bitplane;
   (iii) decoding the signs of said newly-significant coefficient list entries;
   (iv) removing said newly-significant entries from the coefficient list.

(c) means for reordering significant coefficients removed from the coefficient list to a set of frequency-domain output coefficients.

According to a further aspect of the present invention, there is provided an apparatus for encoding audio signals to a layered datastream having a base layer and a predetermined number of enhancement layers, the apparatus comprising:
(a) means for reordering frequency-domain coefficients representing an audio signal to a coefficient list, where the list order preserves the frequency order of coefficients and groups together coefficients with the same frequency index;
(b) means for quantising and coding coefficients corresponding to the base layer with a predetermined bandwidth limit, until a predetermined bit allocation for the base layer is reached;
(c) means for quantising and coding coefficients corresponding to the next enhancement layer with a predetermined bandwidth limit, until a predetermined bit allocation for the enhancement layer is reached;
(d) means for sequentially performing step (c) until all layers have been coded, wherein steps (b), (c) and (d) each includes bitplane coding means for coding quantised coefficient bits of equal significance together in bitplanes, where the bitplane coding means is configured to code bitplanes in order of significance beginning with the most significant bitplane, and coding of one or more bitplanes comprises the steps of:
   (i) locating newly-significant coefficients with most-significant magnitude bit (MSB) positions within the current bitplane, by runlength coding positions of coefficient list entries whose magnitudes equal or exceed a predetermined threshold level corresponding to the current bitplane;
   (ii) coding the signs of said newly-significant coefficients;
   (iii) removing said newly-significant coefficients from the coefficient list.
(f) means for outputting coded layer data to the datastream.

According to a further aspect of the present invention, there is provided an apparatus for decoding audio signals from a layered datastream having a base layer and a predetermined number of enhancement layers, the apparatus comprising:
(a) means for initialising entries in a coefficient list to zero, where the list order preserves the frequency order of coefficients and groups together coefficients with the same frequency index;
(b) means for decoding data from the datastream corresponding to the base layer with a predetermined bandwidth limit, until a predetermined bit allocation for the base layer is reached;
(c) means for decoding data from the datastream corresponding to the next enhancement layer with a predetermined bandwidth limit, until a predetermined bit allocation for the enhancement layer is reached;
(d) means for sequentially performing step (c) until all layers have been decoded, wherein steps (b), (c) and (d) each includes bitplane decoding means for decoding bitplane data corresponding to quantised coefficient bits of equal significance, where bitplanes are decoded in order of significance beginning with the most-significant bitplane, and decoding of one or more bitplanes comprises the steps of:
   (i) decoding runlength codes to locate newly-significant coefficient list entries which have most-significant magnitude bit (MSB) positions within the current bitplane;
   (ii) setting said newly-significant coefficient list entries to a predetermined threshold level corresponding to the current bitplane;
   (iii) decoding the signs of said newly-significant coefficient list entries;
   (iv) removing said newly-significant entries from the coefficient list.
(e) means for reordering significant coefficients removed from the coefficient list to a set of frequency-domain output coefficients.

According to a further aspect of the present invention, there is provided an apparatus for decoding audio signals from a layered datastream having a base layer and a predetermined number of enhancement layers, the apparatus for decoding each frame of coded data comprising:
(a) means for decoding data from the datastream and reconstructing output coefficients corresponding to the base layer with a predetermined bandwidth limit, until a predetermined bit allocation for the base layer is reached or all of the data for the frame has been decoded;
(b) means for decoding data from the datastream and reconstructing output coefficients corresponding to the next enhancement layer with a predetermined bandwidth limit, until a predetermined bit allocation for the enhancement layer is reached or all of the data for the frame has been decoded;
(c) means for sequentially performing step (b) until all layers have been decoded, or until all of the data for the frame has been decoded;
(d) means for transforming reconstructed output coefficients to a time-domain output signal;
(e) filter means for lowpass filtering the time-domain output signal, where the filter means is configured so that the lowpass filter cutoff frequency is dependent on the bandwidth limit of the last layer decoded.

The herein described methods allow the encoding of audio signals to a datastream with fine-grain bitrate scalability. The method involves reordering frequency-domain transform coefficients, and coding coefficient bitplanes in order of significance. Bitplane coding includes the steps of significance map coding and a refinement stage. Significance map coding identifies those coefficients with an MSB within the current bitplane by arranging reordered coefficients into lists and runlength coding the positions of list entries that are newly significant at the current bitplane level. The refinement stage codes lower-significance bits of coefficients identified in earlier bitplanes.

Further, an apparatus encodes time-domain audio signals to a datastream with fine-grain bitrate scalability, the apparatus having means for transforming a time-domain signal to the frequency domain, weighting and reordering the transform coefficients, and coding coefficient bitplanes in order of significance. Means for bitplane coding includes the steps of significance map coding and a refinement stage. Means for significance map coding identifies those coefficients with an MSB within the current bitplane by arranging reordered coefficients into lists and runlength coding the positions of list entries that are newly significant at the current bitplane level. The means for refinement codes lower-significance bits of coefficients identified in earlier bitplanes.

In a method for decoding audio signals from a datastream, involving the steps of decoding data for each coded bitplane, and reordering reconstructed frequency-domain coefficients, bitplane data is decoded with knowledge of the algorithm used to code significance maps in the encoder. Because the encoded signal has been coded in bitplane order, the decoder can operate on any truncated code with a bitrate less than the encoded rate to provide a lower-quality output signal.

A decoding apparatus comprising means for decoding data for each coded bitplane, reordering and inverse weighting reconstructed coefficients, and inverse transforming coefficients to a time-domain output signal, operates with knowledge of the algorithm used to code significance maps in an encoder. Because the encoded signal has been coded in bitplane order, the decoding apparatus can operate on any truncated code with a bitrate less than the encoded rate to provide a lower-quality output signal.

Two classes of bitplane coding algorithm are considered. Fixed-bandwidth algorithms code a fixed bandwidth range of transform coefficients for all bitplanes, which results in datastreams where coding bandwidth is essentially invariant with decoded bitrate. Alternatively layered algorithms restrict the range of coefficient frequencies coded in bitplanes within lower-bitrate layers, and code higher-frequency information in higher layers. Layered bitplane coding results in increased coding bandwidth as decoded bitrate increases, and can result in improved subjective quality at lower bitrates.

In a first fixed-bandwidth bitplane encoding method, frames of quantised transform coefficients representing the input signal are each arranged in sign-magnitude format and reordered to a list of insignificant coefficients (LIC), where reordering clusters together coefficients with the same frequency index. The coefficients are then scanned in bitplane order beginning with the most-significant bitplane, and the positions of newly significant coefficients within the LIC identified by runlength coding for each bitplane. A sign bit is output following the runlength code for each new significant coefficient location, and the coefficient is moved from the LIC to a list of significant coefficients (LSC). Following completion of the LIC scan, LSC entries identified in earlier (more significant) bitplanes are refined for the current bitplane level.

A first fixed-bandwidth bitplane decoding method mirrors the operation of the encoding method. At the start of decoding each frame of data from a datastream, entries in a list of insignificant coefficients are reset to zero. Data is then decoded for each bitplane beginning with the most significant bitplane, and the positions of newly-significant LIC entries identified by decoding runlength codes for each bitplane. A sign bit is also decoded for each significant LIC entry, and the coefficients moved to a LSC. Refinement data is decoded to refine LSC entries identified in earlier bitplanes. Finally the reconstructed coefficients are reordered, inverse weighted and transformed to a time-domain output signal.

A second fixed-bandwidth bitplane encoding method follows the first encoding method but in addition within each bitplane scan extracts coefficients from the LIC which have a higher probability of becoming significant, to form a subsequence which is coded before coefficients that remain in the LIC. A new subsequence is conveniently formed at the beginning of each bitplane scan. Coefficient contexts used to form the subsequence include the presence of significant neighbour coefficients. As for LIC coding, subsequence coding is also performed using runlength codes. Coding the subsequence before the LIC for each bitplane improves coding efficiency for those frames where coding of the final bitplane is only partially completed. A second fixed-bandwidth bitplane decoding method mirrors the operation of the encoding algorithm.

Another method encodes audio signals in a layered manner, where a number of bitrate ranges are defined wherein bitplane scans are constrained to a limited range of coefficient frequencies. This results in a layered datastream where coding bandwidth increases with bitrate, and fine-grain scalability is maintained within each coded layer. The method involves transforming a time-domain signal to the frequency domain, weighting and reordering the transform coefficients, and layered bitplane encoding. Following coding of the base layer with the lowest bandwidth, coding of each enhancement layer includes coefficients to a new bandwidth limit and also codes uncoded data contained within previous layer bandwidth limits. Coding of each bitplane contained within a layer follows the approach established for fixed-bandwidth coding, including significance map coding and a refinement stage.

Layered datastreams may be decoded where coefficients are reconstructed to a progressively higher bandwidth as decoded bitrate increases. The method involves layered bitplane decoding, and subjecting reconstructed coefficients to inverse reordering and weighting processes before inverse transformation to a time-domain output signal. At lower decoded bitrates where the final encoded layer is not decoded, the time-domain output signal is lowpass filtered to attenuate nonlinear artifacts caused by only partially decoding the full bandwidth range of encoded transform coefficients.

A first layered bitplane encoding method broadly follows the first fixed-bandwidth bitplane encoding method, except that the bandwidth of each bitplane scan is constrained to the bandwidth limit of the current layer. Quantised transform coefficients representing the entire bandwidth of the input signal are arranged in sign-magnitude format and reordered to a list of insignificant coefficients (LIC), where reordering clusters together coefficients with the same frequency index. Each layer is then coded in bitplane order beginning with the most-significant bitplane, where each bitplane coding includes scans of both the LIC and a list of significant coefficients (LSC), and the number of LIC entries scanned depends on the bandwidth limit for the current layer. For each bitplane, positions of newly-significant coefficients within the LIC are identified by runlength codes, followed by a sign bit for each new significant coefficient location. Significant coefficients are moved from the LIC to the LSC. Following completion of the LIC scan, LSC entries identified in earlier (more significant) bitplanes are refined for the current bitplane level. Coding of the base layer with the lowest bandwidth is followed by enhancement layers with progressive increases in coding bandwidth, where each enhancement layer contains coded bitplane information to the new bandwidth limit and also uncoded data from earlier layers. A first layered bitplane decoding method mirrors the operation of the encoding algorithm.

A second layered bitplane encoding method may follow the procedure of the first layered bitplane encoding method but in addition within each bitplane scan forms a subsequence of coefficients extracted from the LIC, which is coded before those coefficients that remain in the LIC. A new subsequence is conveniently formed at the beginning of each bitplane scan within each layer. A second layered bitplane decoding method mirrors the operation of the encoding algorithm.

Methods are described for efficiently coding audio transform coefficient bitplanes. The methods achieve high coding efficiency such that audio signals are compressed to relatively compact representations. The coding methods can be executed with algorithms that offer low computational complexity, and do not require Huffman or arithmetic coding.

It will be realised that both the coding and decoding apparatuses described herein may be constituted using a variety of computation means, including distributed systems, well known to those skilled in the art.

### BRIEF DESCRIPTION OF THE DRAWINGS

The invention will now be described, by way of examples which are not intended to be limiting, and with reference to the accompanying drawings, of which;

FIG. 1 is a block diagram showing an audio encoding apparatus that uses bitplane encoding, according to the first embodiment of the invention.

FIG. 2 illustrates an example frequency-domain transform output corresponding to one frame of audio input data for an encoder using a block-switched modified discrete cosine transform.

FIG. 3 shows an example nonuniform time-frequency decomposition of a wavelet packet transform for use in an audio encoder.

FIG. 4 is a flowchart illustrating the operation of a general bitplane encoding algorithm for use in audio encoding apparatus according to the first embodiment of the invention.

FIG. 5 illustrates the significance map and refinement elements of a bitplane coding process.

FIG. 6 is a block diagram showing an audio decoding apparatus that uses bitplane decoding, according to the first embodiment of the invention.

FIG. 7 is a flowchart illustrating the operation of a general bitplane decoding algorithm for use in audio decoding apparatus according to the first embodiment of the invention.

FIG. 8 is a flowchart illustrating the operation of a fixed-bandwidth bitplane encoding algorithm for use in audio encoding apparatus according to the second embodiment of the invention.

FIG. 9 is a flowchart illustrating the operation of the significance map encoding stage of a fixed-bandwidth encoder according to the second embodiment of the invention.

FIG. 10 is a flowchart illustrating the operation of a fixed-bandwidth bitplane decoding algorithm for use in audio decoding apparatus according to the second embodiment of the invention.

FIG. 11 is a flowchart illustrating the operation of the significance map decoding stage of a fixed-bandwidth decoder according to the second embodiment of the invention.

FIG. 12 is a flowchart illustrating the operation of a fixed-bandwidth bitplane encoding algorithm for use in audio encoding apparatus according to the third embodiment of the invention.

FIG. 13 illustrates the coding order for a layered bitplane encoding process in the frequency domain, where each new layer codes coefficients to a new bandwidth limit and also codes uncoded data within previous layer bandwidth limits.

FIG. 14 is a block diagram showing an audio encoding apparatus using layered bitplane encoding, according to the fourth embodiment of the invention.

FIG. 15 is a block diagram showing an audio decoding apparatus using layered bitplane decoding, and including a lowpass output filter, according to the fourth embodiment of the invention.

FIG. 16 illustrates nonlinear high-frequency artefacts at the output of a layered bitplane decoder when data for the final encoded layer is not decoded.

FIG. 17 is a flowchart illustrating the operation of a layered bitplane encoding algorithm for use in audio encoding apparatus according to the fifth embodiment of the invention.

FIG. 18 is a flowchart illustrating the operation of a layered bitplane encoding algorithm for use in audio encoding apparatus according to the sixth embodiment of the invention.

FIG. 19 is a block diagram showing an audio transcoding apparatus with a datastream input and a scalable datastream output, according to the seventh embodiment of the invention.

FIG. 20 is a block diagram showing an audio transcoding apparatus with a scalable datastream input and a datastream output, according to the seventh embodiment of the invention.

### DETAILED DESCRIPTION OF PREFERRED EMBODIMENTS

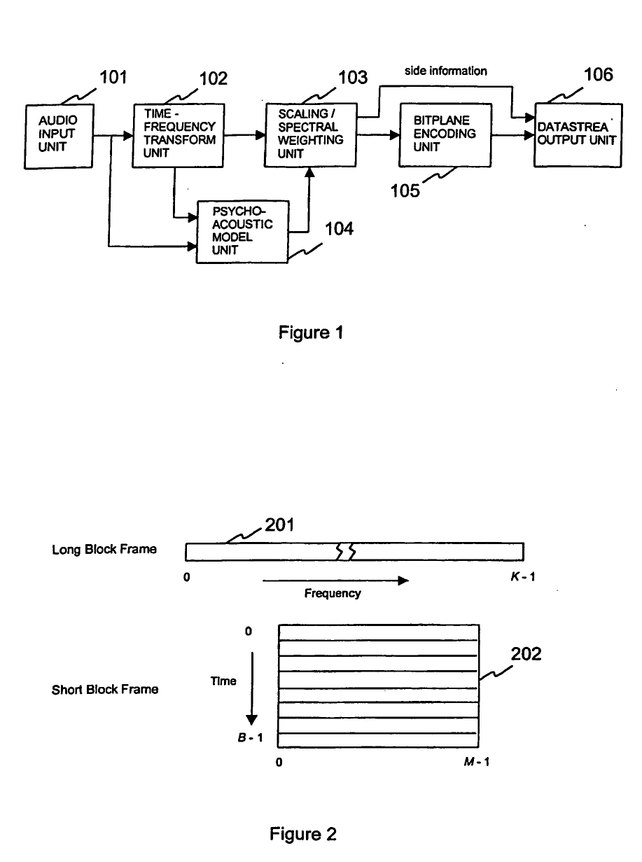

Referring to FIG. 1, an encoding apparatus comprises an audio input unit 101, a time-frequency transform unit 102, a scaling and weighting unit 103, a psychoacoustic model unit 104, a bitplane encoding unit 105, and a datastream output unit 106.

In the description of this embodiment it is assumed that single-channel (monaural) sampled (discrete-time) audio data having 16 signed integer bits per sample is to be encoded. It is further assumed that the sampling rate of the audio data is sufficient to support the full audio spectrum of 0 to 20 kHz, for example a sampling rate of 48 kHz. However, the invention is not limited thereto, but is also applicable to encoding single-channel audio data with other resolutions and sampling rates, for example 12-bit data sampled at 16 kHz. The invention is also applicable to encoding multi-channel audio data.

The operation of each unit of the embodiment will be described in detail.

Audio data to be encoded is successively input from the audio input unit 101 as frames of time-domain samples. The audio input unit 101 may be the output interface of an analog-to-digital converter (ADC) used to digitise a continuous-time (analog) audio signal, an interface to a hardware network, or the like. The audio input unit 101 may also be a storage device such as a RAM, a ROM, a hard disk, and a CD-ROM. A typical frame length is 1024 samples.

Time-domain data from the audio input unit 101 is converted to frequency-domain data by the time-frequency transform unit 102. One possible form of transform is the modified-discrete cosine transform (MDCT) (as used in MPEG-2 AAC for example), where adjacent blocks of samples are windowed and transformed to the frequency domain. For a frame of K time-domain input samples, the frequency-domain transform output can be arranged as a series of B blocks, each with M coefficients ranging from dc to half the sampling frequency, where to preserve critical sampling K=BM.

MDCT transform coefficients can be indexed with a frequency index m, and time index b:
MDCT output ═X[m][b],
   where
      m=0 . . . M−1
      b=0 . . . B−1.

B and M respectively determine the time and frequency resolution of the transform output in each frame—higher B results in better time resolution, whereas increasing M improves frequency resolution. Time/frequency resolution can be adapted to the characteristics of the input signal by using block switching, where FIG. 2 shows longer transform windows 201 (larger M) used for stationary signal frames, and shorter window lengths 202 (smaller M) used under transient conditions.

M) used for stationary signal frames, and shorter window lengths 202 (smaller M) used under transient conditions.

An alternative to the block-switched MDCT is the wavelet packet (WP) transform, which can be arranged to achieve a nonuniform decomposition where time and frequency resolution vary as a function of frequency.

Increasing the time resolution at the expense of frequency resolution for higher-frequency subbands can achieve a time-frequency resolution that approximates that of the hearing system, allowing good transient performance without the use of block switching.

M-band wavelet packet transform coefficients can be indexed with a subband frequency index m, and time index b, where the number of subband samples per frame Bm depends on the decomposition depth for each subband:
WPoutput=X[m][b],
where
   m=0 . . . M−1
   b=0 . . . Bₘ−1

For critical sampling the following relationship holds for the WP transform:

$${\sum }_{m = 0}^{M - 1} {B}_{m} = K .$$

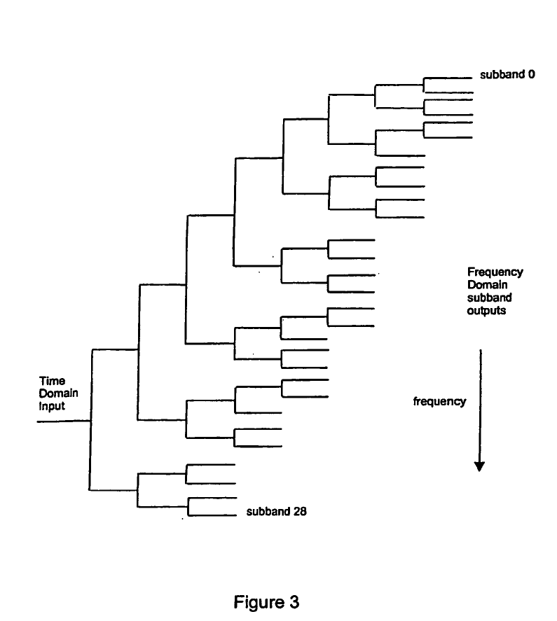

FIG. 3 shows an example 29-band wavelet packet decomposition for use in an encoder, where each of the tree branches represents a lowpass-highpass filter pair and decimation process. If this transform is used with a frame length of 1024 samples, the lowest-frequency subband outputs will contain 4 samples per frame (Bₘ=4), while the highest frequency subband outputs will contain 128 samples per frame (Bₘ=128).

It is also possible to obtain a nonuniform decomposition with an MDCT-based system by combining high-frequency coefficients.

In a scalable compression system it is desirable to quantise and code the transform output for each frame in an embedded manner, allowing the resultant datastream to be truncated to a lower-rate representation that remains decodable. Embedded coding is conveniently achieved using bitplane coding. One of the characteristics of bitplane coding is that because in each bitplane scan the same threshold level is used to construct codes for all coefficients, the resultant quantisation error will tend to a white spectrum. Such an error characteristic is sub-optimal for audio coding because masking results in a nonuniform spectral sensitivity to quantisation error. Spectral error shaping can reduce error audibility, and can be achieved by weighting the transform output prior to bitplane encoding, and performing an inverse weighting at the decoder following bitplane decoding.

Referring again to FIG. 1, in the present embodiment the transform output coefficients are input to a scaling and spectral weighting unit 103 prior to bitplane encoding. In general the transform output coefficients will be in floating-point format even if the time-domain input samples are of integer format. A scaling operation scales the magnitudes of all transform coefficients in a frequency-independent manner so that they occupy a sufficiently large integer range prior to bitplane encoding. The scaling operation is fixed and does not change from frame to frame. A spectral weighting operation provides a frequency-dependent weighting of scaled transform coefficients X(k),

$${X}^{′} ( k ) = \frac{X ( k )}{W ( k )} , \qquad for k = 0 … K - 1.$$

where the weighting function W(k) follows the desired error shaping function, and X′(k) represents the scaled and weighted transform coefficients. One approach is to set the weighting function for each frame so that error shaping approximates the masked threshold for the frame, determined by a psychoacoustic model unit 104. The weighting function is coded to the datastream as side information for each frame so that a decoder can provide the correct inverse weighting. The overhead corresponding to weight side information can be minimised by quantising and entropy coding the weighting function across banded coefficient groups. An example weighting scheme consists of 32 band weights quantised in 3.0 dB steps, where the band widths approximate the critical band law of the hearing process.

The scaled and weighted transform coefficients X′(k) are then input to a bitplane encoding unit 105, where coefficient bits of equal significance are grouped together into bitplanes, and each bitplane coded in order of significance.

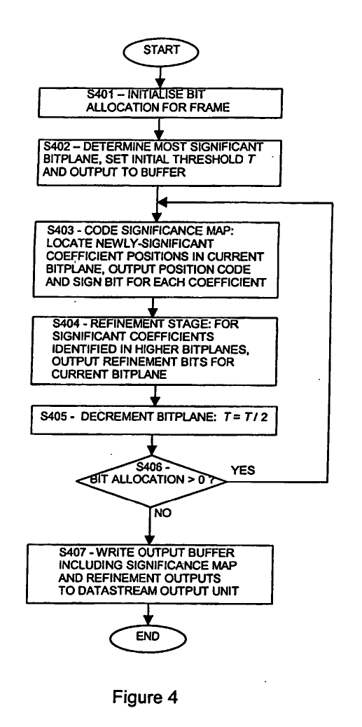

A general bitplane-encoding algorithm 105 is shown as a flowchart in FIG. 4. At step s401 a bit allocation variable is initialised to the required size of the coded frame, and is subsequently updated as data is coded in order to indicate the number of bits which are available to code further data for the frame. Scaled and weighted floating-point transform coefficients X′(k) are represented in sign-magnitude format, and at step s402 the largest coefficient magnitude within the frame |X′|ₘₐₓ is determined and an initial threshold level T set such that
T≦|X′|ₘₐₓ [symbol] 2T.

T determines the current bitplane level in the encoding process, and the most significant bitplane within the frame is coded with the initial threshold value. The initial threshold value is output as side information to an output buffer for coded frame data, so that a decoder receiving a coded datastream can begin decoding at the correct bitplane level.

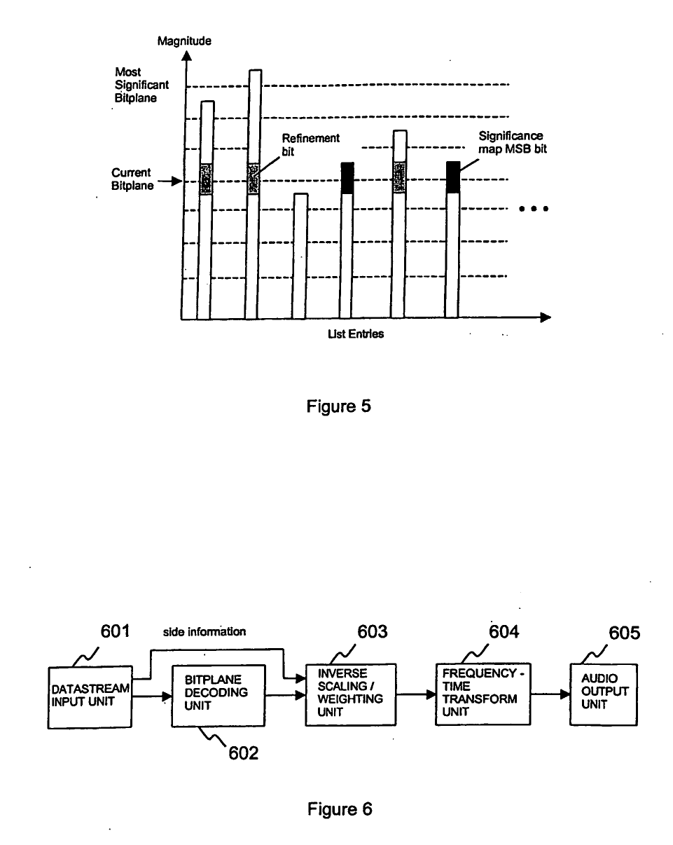

For each bitplane coefficients are scanned at step s403 to locate those with magnitudes equal to or exceeding T—these coefficients are termed ‘significant’ with respect to the current threshold. With reference to FIG. 5, data describing newly significant coefficient locations within each bitplane—ie the positions of coefficients that have their MSB located within the current bitplane is termed a ‘significance map’. When a significant coefficient is located, the component of the significance map describing the location is coded and output to the output buffer, followed by a sign bit representing the sign of the coefficient. Less-significant bits of significant coefficients are termed ‘refinement’ bits.

When all of the transform coefficients have been scanned at the initial threshold level, T is halved at step s405 and coding progresses to the next bitplane where all coefficients not yet found to be significant are scanned using the new value of T. For each new significant coefficient identified a significance map component and sign bit are coded and output to the output buffer at step s403. When this second significance map is complete a refinement stage s404 is executed where refinement bits corresponding to the new threshold level are output to the output buffer for all significant coefficients identified in the first bitplane scan. The threshold is halved again, and significance map and refinement data coded for the third bitplane. This process is repeated for progressively less significant bitplanes until the bit allocation for the frame is reached, at which point coding terminates (step s406), and at step s407 coded frame data in the output buffer is written to the datastream output unit 106.

In effect the general bitplane coding algorithm described implements uniform quantisation with a dead-zone around zero, where integer quantised coefficient values are given by

$$q ( k ) = sgn ( {X}^{′} ( k ) ) ⌊ \frac{{X}^{′} ( k )}{{T}_{F}} ⌋$$

and T_{F} is the final threshold value used to code each coefficient.

In general, significance map coding at step s403 is achieved in embodiments of the present invention by forming lists of coefficients, testing list entries for significance with respect to threshold T, and outputting significance test results to the output buffer. A simple coding approach is to output a single bit for each list entry tested—for example, ‘0’ and ‘1’ could indicate insignificant and significant entries respectively. However, unless the probability of significance s is close to 0.5 then this coding method is relatively inefficient. Often s<<0.5, in which case improved coding efficiency can be achieved by runlength coding the significant entry locations within a list.

A useful runlength code is the Golomb code with parameter p, where non-negative runlength r is coded as 2 components—a prefix └r/p┘ coded in unary, followed by suffix [r mod p] coded in binary. A particularly simple form of Golomb code, sometimes known as Rice codes, occurs when p=2ⁿ for some integer n≧0—here r can be coded by removing the n least-significant bits from r, coding the remainder as a unary prefix, and appending n binary LSB's. For example, if r=9 and n=2, then the Golomb-Rice code for r is ‘00101’—here the prefix is ‘001’=8, and the remainder is ‘01’=1.

It should be noted that the configuration of Golomb runlength codes is not limited only to that used in the above embodiment, where the variable-length prefix is coded as ‘0’s followed by a ‘1’, and is followed by the fixed-length suffix. Instead, the use of ‘0’s and ‘1’s may be reversed to code the variable-length part. Further, the Golomb code may be coded as a fixed-length part followed by a variable-length part.

The coding efficiency achieved using Golomb-Rice codes to runlength code significant entry locations in a list depends on the code wordlength n and the runlength distribution. n can be set to a fixed value which on average results in the most compact list code across many frames of a test item. Alternatively n can be optimised for each frame, and sent as side information at the start of the frame so that a decoder can correctly interpret the coded list data. Yet another approach is to optimise n for each bitplane of each frame, and send the appropriate side information at the start of each bitplane.

A different approach to adapting the runlength coder wordlength to the runlength statistics of a list is to make the Golomb-Rice code adaptive in the sense that n varies as a function of list data coded—that is, backwards-adaptive runlength coding. An adaptive code such as that described by Langdon Jr could be used (“An Adaptive Run-Length Coding Algorithm,” IBM Technical Disclosure Bulletin, vol. 26, pp. 3783-3785 (1983 December)), where each ‘0’ in the unary-coded prefix causes the wordlength n to increment, and n is decremented following the binary-coded suffix. For example, consider the code for r=9 with an initial wordlength n=2: the adaptive Golomb-Rice code for r is 01101—here the prefix is ‘01’=4, the 3-bit remainder is ‘101’=5, and the final value for n is 2. While this example considers the case where n increases or decreases by 1 for each prefix ‘0’ or suffix output, it is also possible to construct adaptive runlength codes which adapt at different rates to adaptation instances—for example, where n increases by 1 for every second prefix ‘0’ output (as described in WO0059116, Malvar). Of course other adaptation strategies also exist (E. Ordentlich, M. Weinberger, and G. Seroussi, “A Low-Complexity Modeling Approach for Embedded Coding of Wavelet Coefficients,” Proc. IEEE 1998 Data Compression Conference, Snowbird, Utah, pp. 408-417 (1998 March)). The advantages of using adaptive Golomb-Rice codes to scan for significant entries within lists includes the simplicity and computational efficiency of the codes, and also the efficiency with which the codes can adapt to changing runlength statistics within a list, which results in relatively compact list coding without the use of wordlength side information.

Another form of adaptive runlength code is the exponential-Golomb code, or exp-Golomb code (J. Teuhola, “A Compression Method for Clustered Bit-Vectors,” Information Processing Letters, vol. 7, pp. 308-311 (1978 October)). Here the code wordlength n is set to a fixed value at the start of each code, and increments for each prefix ‘0’ coded. An interesting aspect of exp-Golomb codes is that with minor modifications they can form reversible variable length codes (RVLCs), where the code prefix can be decoded in either a forward or reverse direction (J. Wen and J. D. Villasenor, “Reversible Variable Length Codes for Efficient and Robust Image and Video Coding,” Proc. 1998 IEEE Data Compression Conference, pp. 471-480, Snowbird, Utah (1998 March)). RVLCs can improve coding robustness with error-prone transmission channels. Note that RVLCs with the same length distributions as fixed-wordlength Golomb-Rice codes can also be formed.

When fixed- or adaptive-Golomb-Rice codes are used to scan lists for significant entries, coding the end of the list scan following the final significant entry location can be simply achieved by outputting a series of prefix ‘0’s until the end of the list is passed. When a decoder receives coded list data and the current list position passes the known list length, all remaining list entries following the last significant position are marked as insignificant and decoding of the current list terminates. End-of-run codes in this fashion are particularly compact when an adaptive Golomb-Rice code is used. For example, with the runlength adaptation rule described above and a list length of 1024 entries, end-of-run codes are represented with a maximum of eleven prefix ‘0’s.

Returning again to FIG. 1, the final stage of the encoding process is to transmit to a memory or an external apparatus the bitplane encoded data stored in the output buffer, and also side information such as banded weight data, by means of a datastream output unit 106. The datastream output unit 106 may be a storage device such as a hard disk, a RAM, and a CD-ROM, or an interface to a public telephone line, a radio line, a LAN or the like.

FIG. 6 is a block diagram of an audio decoding apparatus also according to the first embodiment of the invention. The decoding apparatus comprises a datastream input unit 601, a bitplane decoding unit 602, an inverse scaling and weighting unit 603, a frequency-time transform unit 604, and an audio output unit 605.

Coded data frames representing bitplane-encoded audio data are received by a datastream input unit 601. The datastream input unit 601 may be a storage device such as a hard disk, a RAM, and a CD-ROM, or an interface to a public telephone line, a radio line, a LAN or the like.

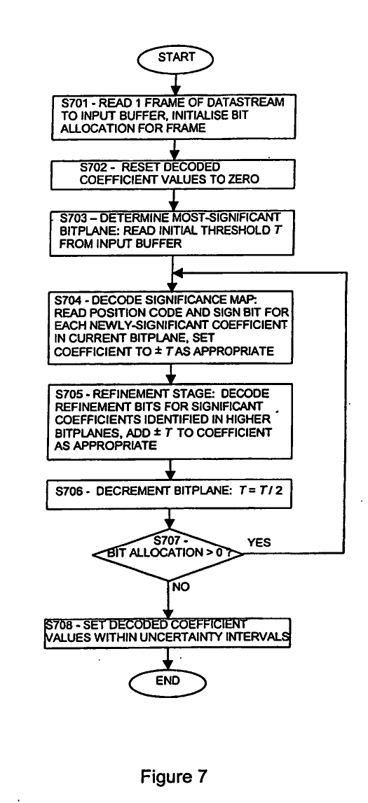

The coded data is input to a bitplane decoding unit 602 that reconstructs transform coefficients in bitplane order. FIG. 7 shows a general bitplane decoding algorithm 602, where decoding of each frame begins at step s701 by storing coded data for the frame in an input buffer, and using the amount of coded data read for the frame to initialise a bit allocation variable. Before decoding the first bitplane the output coefficient values are reset to zero at step s702. An initial threshold level T read from the input buffer at step s703 then determines the most significant (initial) bitplane level for the frame. For each bitplane scan, significance map data read and decoded from the input buffer at step s704 identifies coefficients whose MSB is located in the current bitplane and the corresponding sign bits. These coefficients are set to ±T as appropriate to the sign of the coefficient. Refinement data decoded at step s705 is used to refine lower-significance bits of significant coefficients identified in previous bitplanes, and for each refinement bit received ±T is added to the decoded coefficient value as appropriate. When data for the current bitplane has been read and decoded, T is halved at step s706 and decoding progresses to the next bitplane. This process continues until no more coded data is available to decode, at which point decoding for the current frame terminates at step s707. Because the coded data has been encoded in bitplane order, the decoder can reconstruct data to a lower precision simply by discarding data for less-significant bitplanes.

For each significant coefficient identified in the decoding process there exists a range of uncertainty concerning the reconstructed value, which depends on the threshold T_{F} corresponding to the final significant bit decoded for the coefficient. A simple reconstruction approach is to set each significant coefficient to the center of its uncertainty interval at step s708 by adding ±0.5T_{F}, depending on the sign of the coefficient.

Referring again to FIG. 6, decoded bitplane data is input to an inverse scaling and weighting unit 603, where a fixed and frequency-independent scaling operation complementary to that implemented in the encoder is applied to all decoded coefficient values \tilde{X}′(k). Side information received from the datastream input unit 601 and representing banded weight values W(k) is then used to implement an inverse weighting process on the scaled coefficients,
\tilde{X}(k)=\tilde{X}′(k)W(k), for k=0 . . . K−1,
where \tilde{X}(k) represents reconstructed coefficient values following inverse scaling and weighting.

A frequency-time transform unit 604 then transforms blocks of decoded coefficients \tilde{X}(k) to the time domain. If the transform is an inverse modified discrete cosine transform (IMDCT) this process involves transforming and windowing adjacent blocks of coefficients to the time domain. An alternative transform is the inverse wavelet packet transform.

Time-domain data representing decoded sampled (discrete-time) data for each frame is output using an audio output unit 605. The audio output unit 605 may be a digital-to-analog converter (DAC) used to convert decoded data to a continuous-time audio signal, an interface to a hardware network, or the like. The audio output unit 605 may also be a storage device such as a RAM, a hard disk, and a CD-ROM.

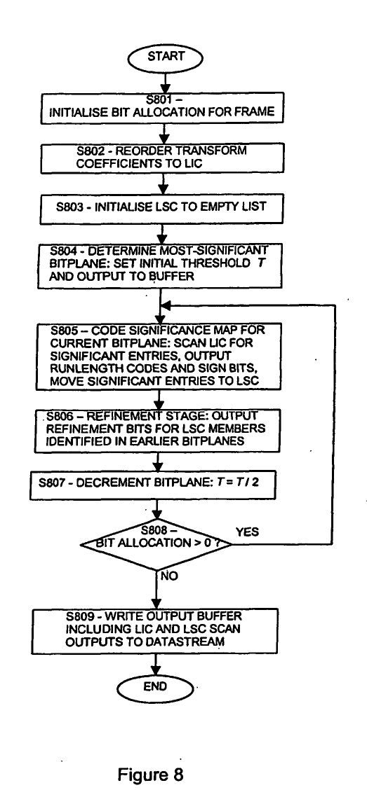

Referring once again to FIG. 1, the bitplane encoding unit 105 codes coefficient bitplanes in order of significance. The operation of an example bitplane encoding process 105 for one frame of audio data using a fixed-bandwidth bitplane coding algorithm of the second embodiment of the invention will now be described with reference to FIG. 8.

The first step s801 of the encoding algorithm initialises a bit allocation variable for the frame. Then at step s802 transform coefficients are reordered to a list of insignificant coefficients (LIC), and at step s803 a list of significant coefficients (LSC) is initialised to an empty list. Then for each bitplane, beginning with the most significant bitplane determined at s804, a runlength coder is used to identify newly-significant coefficient locations within the LIC (step s805), followed by a refinement stage s806 that outputs less significant bits of significant coefficients identified in earlier bitplanes.

The reordering step s802 involves mapping scaled and weighted transform coefficients X′(k) representing the frame to the LIC in a data-independent manner such that coefficients with the same frequency index are clustered together within the LIC. Since coefficients with the same frequency index tend to be of similar magnitude, the reordering operation has the effect of clustering significant coefficient locations within LIC scans. This results in longer runs of insignificant coefficients which can improve coding efficiency when runlength coded at step s805, particularly when using adaptive runlength codes.

When the transform is an MDCT the reordering at s802 can be described by

$$\begin{matrix}\begin{matrix}LIC ( k ) = {X}^{′} [ m ] [ b ] , & & for k = 0 … K - 1 ,\end{matrix} \\ where \\ m = ⌊ \frac{k}{B} ⌋ , \\ b = k mod B .\end{matrix}$$

When a frame contains only a single block of MDCT coefficients (long block mode, B=1), the reordering operation is the trivial task of copying the coefficients to the LIC in frequency order,
LIC(k)=X′[k][0].

When a frame contains several short MDCT blocks (B>1), coefficients with the same frequency index are clustered (grouped) together within the LIC. This operation can be viewed as a short block interleaving process.

A similar mapping is made when the transform is a wavelet packet transform, grouping together all coefficients with the same subband frequency index within the LIC.

Note that the above embodiment describes the case where the full-bandwidth range of transform coefficients is mapped to the LIC, and the LIC length is equal to the frame length K. In this case coding of each bitplane will cover a full-bandwidth set of coefficients. However a reduced-bandwidth set of coefficients can also be coded by discarding high-frequency coefficients from each block in the reordering process, in which case the LIC length will be less than K. For both cases the coding bandwidth is constant for all bitplanes within a frame.

Following coefficient reordering at step s802 and LSC initialisation at step s803, the magnitude of the largest LIC entry is used to set an initial threshold level T at step s804, which determines the most significant bitplane. Before coding the first bitplane, T is output to an output buffer at step s804.

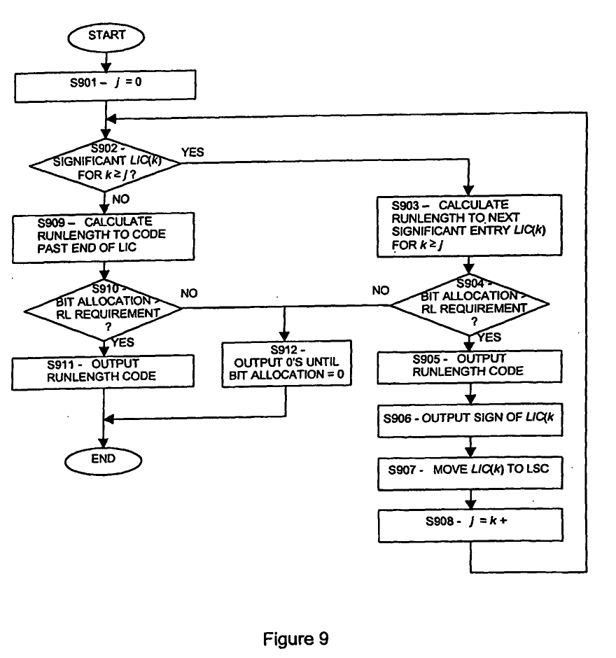

Significance map coding of each bitplane (s805) involves scanning the LIC for significant entries, using runlength codes to determine k for which LIC(k)≧T. FIG. 9 shows a flowchart illustrating the significance map encoding step s805. At step s901 the current bitplane scan position is initialised to the start of the LIC by setting j=0. At step s902 the remaining LIC members are scanned for significant entries where |LIC(k)|≧T, and k set to the first significant entry at or beyond j. If significant entries exist, the runlength between j and k is calculated, and the number of bits required to code the runlength and sign bit calculated at s903. If sufficient bits remain from the overall bit allocation for the frame (s904), the runlength code is output to the output buffer (s905) followed by a coefficient sign bit (s906). The significant coefficient is then moved from the LIC to the list of significant coefficients (LSC) at step s907, and will be scanned during refinement passes in future (less significant) bitplanes. The current scan position is updated to point to the next LIC entry at step s908, and coding progresses to the next significant LIC entry. During significance map scans of less-significant bitplanes, the LIC position previously occupied by the significant coefficient at k is skipped, and does not contribute to future runlength codes.

If the test at s904 indicates insufficient bits remain from the overall bit allocation with which to code the next runlength code and sign bit of the LIC scan, then zeros are output to the output buffer until the bit allocation for the frame is reached (s912), and coding for the current frame terminates.

The end of each LIC scan following the final significant LIC entry can be simply coded by outputting a runlength code which causes the bitplane scan position to pass the end of the LIC (s909, s910, s911). As discussed above in the first embodiment, when Golomb codes are used for runlength coding, the end of an LIC scan can be compactly coded by outputting a series of prefix ‘0’s until the end of the LIC is passed.

The coding efficiency of the significance map stage is determined by the runlength statistics of each bitplane and the runlength coding used. If a fixed Golomb-Rice runlength code is used where wordlength n is fixed for all bitplanes of all frames, an optimal value for n is selected which on average results in the most compact significance map code. Alternatively n can be optimised for each frame at a certain target bitrate and sent as side information at the start of each frame, or optimised for each bitplane of each frame and sent as side information at the start of each bitplane.

An alternative to using a fixed runlength code is to use an adaptive Golomb-Rice code where wordlength n varies as a function of data coded in each bitplane. A suitable adaptation strategy is to increment n for each runlength prefix ‘0’ bit output, and to decrement n following a runlength suffix code. For bitplanes of audio transform coefficients the average spacing between significant LIC entries tends to increase with frequency, and coding efficiency is improved by resetting the runlength coder wordlength to a small value at the beginning of each bitplane scan (step s901)—in practice resetting n to 0 or 1 yields good results.

Referring again to FIG. 8, whereas the LIC scan at step s805 determines the MSB position of each significant coefficient, LSB information is provided during refinement stage scans of the LSC (s806). For each LSB coded the probability of coding a ‘1’ is close to that of coding a ‘0’, hence the LSC scan is efficiently performed by outputting a single bit for each list entry. If insufficient bits remain from the overall bit allocation for the frame with which to code the next refinement bit, then zeros are output until the bit allocation for the frame is reached, and coding for the current frame terminates.

Following significance map (LIC) and refinement (LSC) scans at the current threshold level T, coding for the current bitplane is complete. T is then halved at step s807 and coding continues to the next bitplane. Coding terminates when, at any stage within a bitplane scan, the bit allocation for the frame is reached (for example, at step s808). When coding for the current frame is completed, output buffer data is written to the datastream output unit 106 at step s809, and the buffer emptied in anticipation of the next frame to be coded.

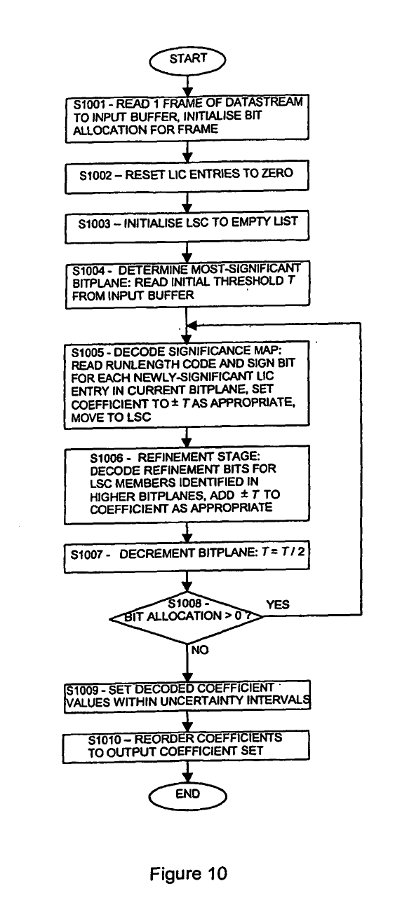

Referring again to FIG. 6, the bitplane-decoding unit 602 decodes bitplane-coded coefficient data, where each bitplane contains information for a fixed-bandwidth coefficient set. The operation of an example bitplane decoding process according to the second embodiment of the invention will now be described with reference to FIG. 10.

In general the decoding algorithm mirrors the operation of the encoding algorithm (FIG. 8). At step s1001 a frame of coded data is read from the datastream input unit 601 to an input buffer, and a bit allocation variable initialised to the amount of data read for the frame. At s1002 a K-sample LIC is initialised and member coefficients reset to zero. A LSC is initialised to an empty list at step s1003. An initial threshold value T corresponding to the most significant bitplane for the frame is read from the input buffer at s1004, and coefficients reconstructed in bitplane order by decoding LIC significance map data (s1005) and LSC refinement data (s1006) for each bitplane. At the end of decoding each bitplane, T is halved (s1007) and decoding progresses to the next bitplane. When no more bits are available in the input buffer to decode, bitplane decoding terminates (s1008), and significant coefficients are set within their uncertainty intervals at step s1009. Finally coefficients are reordered to an output coefficient set at s1010, where reordering de-interleaves coefficients with the same frequency index to their respective transform blocks.

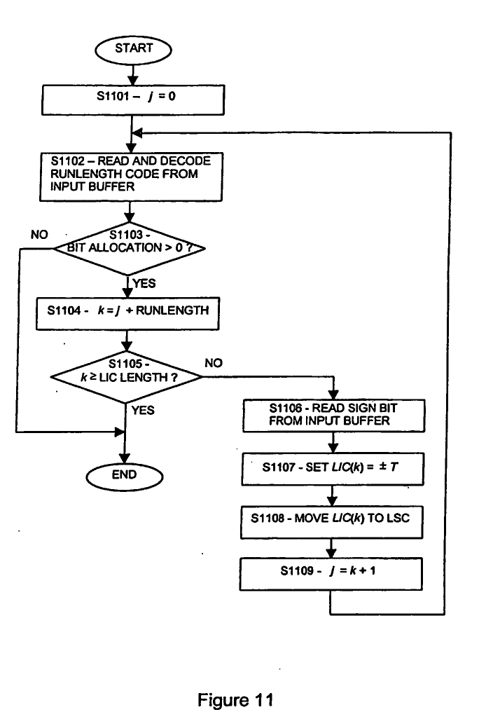

FIG. 11 shows a flowchart illustrating the significance map decoding stage at s1005. At step s1010 the scan position for the current bitplane is initialised to the start of the LIC by setting j=0. Also at s1101 if fixed Golomb-Rice runlength codes are to be decoded, any wordlength side information for the runlength decoder is read from the input buffer as required. If adaptive Golomb-Rice codes are to be decoded, the decoder wordlength is reset to a small value at s1101. Then at s1102 a runlength code is read from the input buffer and decoded. If bits remain in the input buffer for the current frame (s1103), an LIC index k is obtained at s1104 by adding the runlength to j. If k is within the bounds of the LIC (s1105), a sign bit is read from the input buffer (s1106) and the MSB of the LIC member set to the current bitplane by setting LIC(k)=±T as appropriate (s1107). The significant coefficient is then moved from the LIC to the LSC at step s1108, the current scan position updated to the next LIC position (s1109), and the next runlength code read and decoded from the datastream at step s1102. Note that if the LIC index k is beyond the end of the LIC at s105, then significance map decoding for the current bitplane terminates.

Referring again to FIG. 1, the bitplane encoding unit 105 codes a fixed-bandwidth set of coefficients in each bitplane. The operation of an example bitplane encoding process 105 using a fixed-bandwidth bitplane coding algorithm of the third embodiment will now be described. This bitplane encoding method is similar to that of the second embodiment, but is enhanced by extracting LIC coefficients to form a subsequence which for each bitplane significance scan is coded before the remaining LIC coefficients.

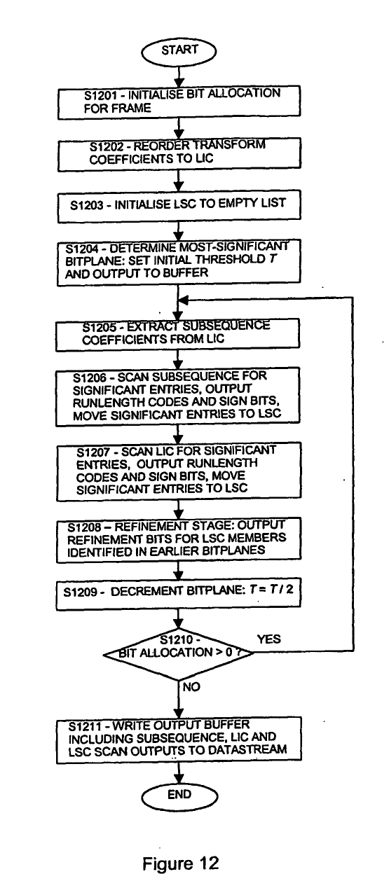

With reference to FIG. 12, the first step s1201 of the encoding algorithm initialises a bit allocation variable for the frame. Then at step s1202 transform coefficients are reordered to a list of insignificant coefficients (LIC), where as before the reordering process groups together coefficients with the same frequency index within the LIC. At step s1203 a list of significant coefficients (LSC) is initialised to an empty list. Then, for each bitplane beginning with the most significant bitplane determined at s1204, a significance map is coded in three stages s1205, s1206 and s1207, which collectively identify coefficients with most-significant magnitude bits in the current bitplane. Also for each bitplane, a refinement stage s1208 outputs less significant bits of significant coefficients identified in earlier bitplanes. The threshold T corresponding to the current bitplane is halved at s1209, and coding progresses to the next bitplane. When the bit allocation has been used, coding for the current frame terminates (s1210), and at step s1211 the contents of the output buffer is written to the datastream output unit 106.

The criteria used to extract coefficients from the LIC to form a subsequence at s1205 is that the extracted coefficients should have a higher expected probability of becoming significant in the pending bitplane scan than those coefficients that remain in the LIC. Suitable contexts for selecting coefficients to form the subsequence include:
coefficients that are frequency-domain neighbours to significant coefficients with the same time index
for frames containing more than one transform block (B>1), coefficients that are time-domain neighbours to significant coefficients with the same frequency index
the significant neighbour ‘age’, or the bitplane difference between the significant neighbour MSB bitplane and the current bitplane
coefficients that have some harmonic relationship to significant coefficients.

Note that while coefficient extraction can in theory take place at any point(s) within a bitplane scan, in practice a convenient point at which to form the subsequence is at the start of each bitplane scan (as shown for s1205 in FIG. 12).

The subsequence is coded at s1206 by scanning for significant entries using runlength codes. A suitable runlength code is a fixed or adaptive Golomb code. When a significant entry is found a sign bit is output to the output buffer and the coefficient is moved from the subsequence to the LSC. Coding the subsequence at s1206 before the remaining LIC coefficients at step s1207 results in improved coding efficiency for those frames where the final bitplane scan is only partially completed.

Following subsequence coding, the LIC is scanned for significant entries at s1207, also using runlength codes in a similar fashion to the method of the second embodiment (FIG. 9). If a fixed Golomb-Rice runlength code is used where wordlength n is fixed for all bitplanes of all frames, an optimal value for n is selected which on average results in the most compact significance map code. Alternatively n can be optimised for each frame at a certain target bitrate and sent as side information at the start of each frame, or optimised for each bitplane of each frame and sent as side information at the start of each bitplane. If an adaptive Golomb-Rice code is used then n is reset to a small value at the beginning of each bitplane scan (ie beginning of step s1207).

Referring once again to FIG. 6, the bitplane-decoding unit 602 decodes bitplane-coded coefficient data, where each bitplane contains information for a fixed-bandwidth coefficient set. The operation of a bitplane decoding process 602 according to the third embodiment of the invention (not shown) is similar to that of the second embodiment (FIG. 10), except that for each bitplane the significance map is decoded in three steps to mirror the operation of the encoding process shown in FIG. 12. Hence for each bitplane, significance map decoding comprises the steps of subsequence formation using the same context rules used in the encoder, decoding subsequence runlength codes and sign bits, and decoding LIC runlength codes and sign bits.

The fixed-bandwidth coding algorithms described for previous embodiments code a fixed frequency range of transform coefficients together in each bitplane, where coding bandwidth is invariant with bitrate. While fixed-bandwidth coding results in good subjective quality at higher bitrates, coding quality can decrease at lower bitrates where on average fewer bits are available to code each significant coefficient. At lower bitrates improved subjective quality can be achieved by limiting the bandwidth of each bitplane scan, essentially because on average more bits are allocated to each significant coefficient coded. Ideally the coding bandwidth should be constrained to a fixed value within a defined bitrate range, so that consecutive frames decoded at the same bitrate have the same bandwidth. This avoids consecutive frames being decoded to different bandwidths, which can result in uncancelled transform alias products.

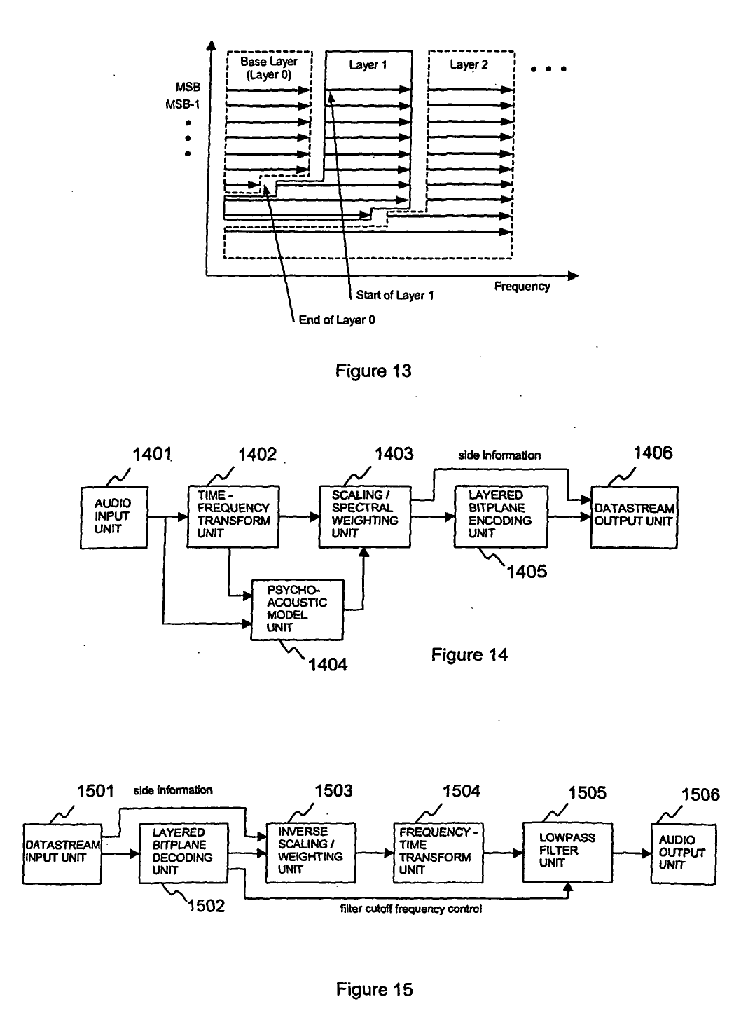

Defining a number of bitrate ranges where encoder bitplane scans are constrained to a limited range of coefficient frequencies results in a ‘layered’ datastream where coding bandwidth increases with bitrate, and fine-grain scalability is maintained within each coded layer. Referring to FIG. 13, following coding of the base layer with the lowest bandwidth, each enhancement layer codes coefficients to a higher bandwidth limit, and can also code uncoded coefficient data from previous layer bandwidth limits.

FIG. 14 is a block diagram of an audio encoding apparatus according to the fourth embodiment of the invention. The encoding apparatus comprises an audio input unit 1401, a time-frequency transform unit 1402, a scaling and weighting unit 1403, a psychoacoustic model unit 1404, a layered bitplane encoding unit 1405, and a datastream output unit 1406. These processes operate in a similar manner to those of the first embodiment (FIG. 1), except that bitplanes are encoded in a layered manner by the layered bitplane encoding unit 1405, and the datastream output unit 1406 interleaves layered bitplane data with banded weight side information to yield a layered datastream output.

FIG. 15 is a block diagram of an audio decoding apparatus according to the fourth embodiment of the invention. The decoding apparatus comprises a datastream input unit 1501, a layered bitplane decoding unit 1502, an inverse scaling and weighting unit 1503, a frequency-time transform unit 11504, a lowpass filter unit 1505, and an audio output unit 1506. The datastream-input unit 1501, scaling and weighting unit 1503, transform unit 1504 and audio output unit 1506 operate in a similar manner to the equivalent processes of the first embodiment (FIG. 6).

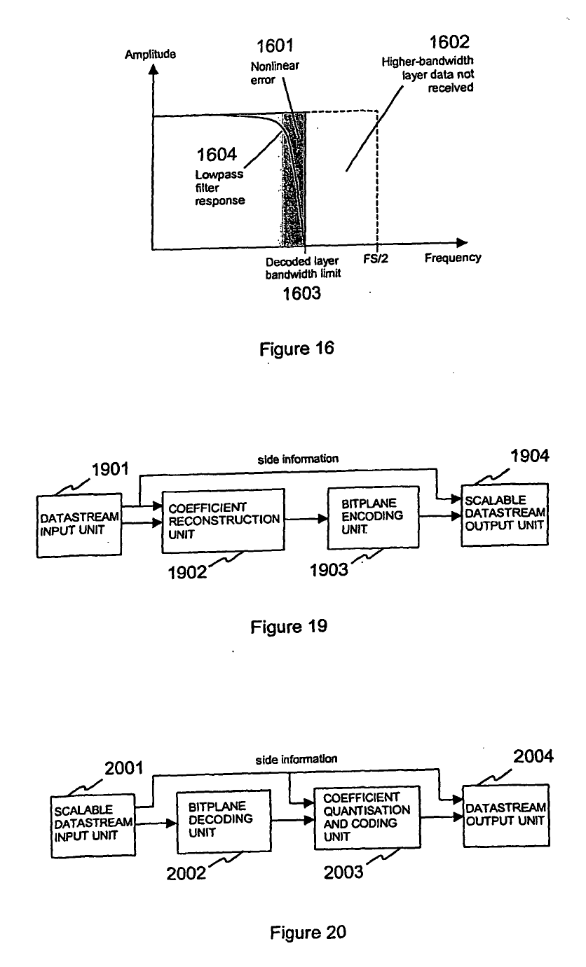

The layered bitplane-decoding unit 1502 reconstructs coefficients in layer and bitplane order. At lower decoded bitrates coefficients can only be recovered within a limited bandwidth range, defined by the bandwidth limit of the last layer decoded. With reference to FIG. 16, this can cause nonlinear artifacts 1601 in the time-domain output following frequency-to-time transformation 1504 if the final encoded layer is not decoded, due to the missing high frequency coefficients 1602. When the time-frequency transform is an MDCT, the nonlinear artifacts 1601 will appear close to the bandwidth limit 1603 of the last decoded layer, and the frequency range across which errors appear will be a function of transform length and the shape of analysis-synthesis windows.

Low-pass filtering the transform output with a lowpass filter unit 1505 shown in FIG. 15 can reduce the audibility of these errors. The lowpass filter response 1604, defined by a filter cutoff frequency and transition bandwidth, will tradeoff bandwidth against artifact attenuation. Ideally the filter cutoff frequency should track the bandwidth limit 1603 of the last decoded layer. If the decoded bitrate changes from frame to frame, as may occur if the coded datastream is received over a variable-bandwidth channel link, an adaptive filter should be used where the filter cutoff frequency can adapt to variations in the decoded bandwidth limit.

Layered coding schemes based on arithmetic coding and offering fine-grain scalability have previously been described by Park (supra), where arithmetic coding is used to identify newly-significant coefficient locations within each bitplane scan. Conversely, the layered bitplane coding methods described in the embodiments below use runlength coding for the significance map stage of each bitplane scan.

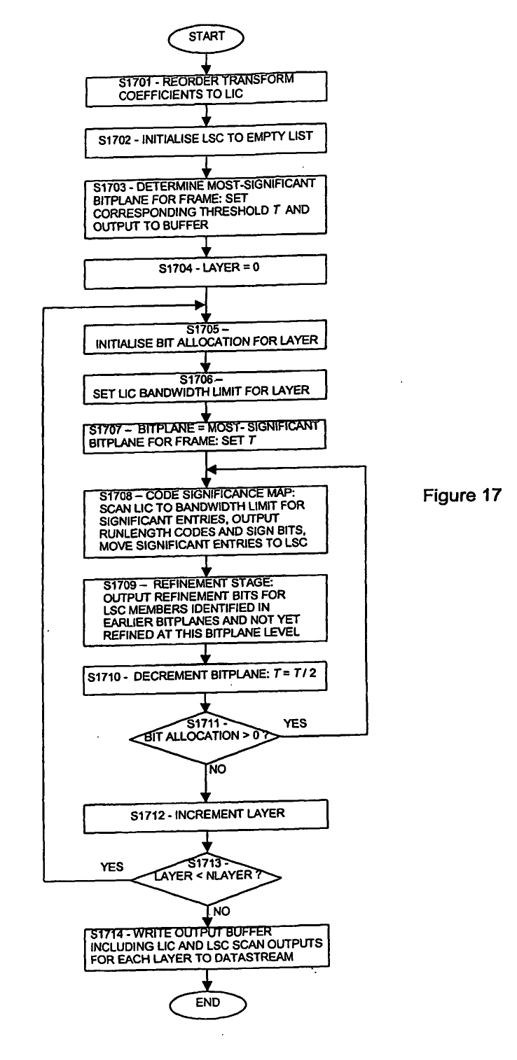

Referring again to FIG. 14, the layered bitplane encoding unit 1405 codes a set of coefficients in each bitplane of each layer which is restricted to coefficient frequencies within the bandwidth limit of the layer. The operation of an example layered bitplane encoding process 1405 according to the fifth embodiment of the invention will now be described with reference to FIG. 17. This process broadly follows the fixed-bandwidth bitplane encoding process of the second embodiment shown in FIG. 8, but embeds list scans within an outer layer loop in order to achieve a layered datastream structure.

With reference to FIG. 17, the layered bitplane encoding process begins at step s1701 by reordering transform coefficients to the LIC in a data-independent manner such that coefficients with the same frequency index are clustered together within the LIC. At step s1702 the LSC is initialised to an empty list. The most significant bitplane across all layers is determined at s103 by finding the largest transform coefficient magnitude within the frame, and a code representing the corresponding threshold level output to an output buffer. Each layer is then coded in turn, beginning with the base layer (s1704).

Each layer is associated with a bit allocation at step s1705, and a bandwidth limit at s1706 that increases with each layer coded. An example bitrate-bandwidth relationship for a 5-layer coder with a transform sampling frequency of 48 kHz and a 1024-sample frame length is shown in table 1:

TABLE 1

| | | | | Layer |
|---|---|---|---|---|
| | | Layer bit | Layer bit | Bandwidth |
| | Bitrate Range | allocation | allocation | Limit |
| Layer | (kbit/s) | (kbit/s) | (bits) | (kHz) |
| 0 | <24.0 | 24.0 | 512 | 4.0 |
| (base) | | | | |
| 1 | 24.0 → 40.0 | 16.0 | 341 | 5.0 |
| 2 | 40.0 → 56.0 | 16.0 | 341 | 8.0 |
| 3 | 56.0 → 72.0 | 16.0 | 342 | 12.0 |
| 4 | ≧72.0 | remainder | remainder | 24.0 |
| | | for frame | for frame | |

At step s1707 coding for each layer begins with the most significant bitplane and continues through lower bitplanes until the bit allocation for the layer has been expended. For each bitplane, the LIC is scanned to the layer bandwidth limit at step s1708 using runlength codes to identify significant entries. If a fixed-wordlength Golomb-Rice runlength code is used for the LIC scan at s1708, then the runlength code wordlength can be optimised for each frame, or each layer, or each bitplane within each layer, and output as side information as appropriate. If an adaptive Golomb-Rice runlength code is used, then the wordlength is reset to a small value at the start of each bitplane within each layer (ie at the start of step s1708). End-of-run's in LIC scans are coded by outputting consecutive ‘0’s until the layer bandwidth limit is passed. When a significant entry is found within step s1708 the runlength code and sign bit are output to the output buffer and the coefficient is moved to the LSC. Significant coefficients identified in earlier bitplanes are refined at the current bitplane level within the LSC scan at step s1709. LSC scans can be efficiently coded by outputting a single refinement bit for each list entry tested.

At step s1710 the threshold T corresponding to the bitplane level is halved, and if bits remain from the bit allocation for the current layer at step s1711, coding progresses to the next bitplane within the layer. If the bit allocation for the current layer has been used at step s1711, and the test at step s1713 indicates this layer is not the final layer, coding progresses to the next layer. Note that while the bit allocation test for the current layer is shown in FIG. 17 at the end of each bitplane scan at step s1711, coding progresses to the next layer if at any point within a bitplane scan the remaining bit allocation for the layer is zero.

For each layer coding begins at step s1707 at the most significant bitplane determined by the largest coefficient in the frame, irrespective of whether this bitplane contains any new significant coefficients within the bandwidth limit for the current layer. If one or more layers contain coefficients much larger than other layers, then the most significant bitplanes of the latter layers will not contain new significant coefficients, and LIC scans for these ‘empty’ bitplanes will be wasteful of bits. Coding efficiency can be improved by outputting a 1-bit flag prior to each LIC scan (s1708), to indicate the presence or otherwise of newly-significant LIC entries within the current bitplane up to the bandwidth limit of the current layer. If newly-significant entries exist then the flag is set to ‘1’ and the LIC is scanned at step s1708. If no significant entries exist then a ‘0’ is output and coding for the current bitplane progresses to the LSC scan at s1709. Note that these bitplane significance flags need not be used for all layers, or for all bitplanes within a layer. In practice good results are usually obtained when flags are used for all layers except the base layer.

As shown in FIG. 13, each enhancement layer can include significance and refinement data for coefficients that originate from any frequency region up to the bandwidth limit of the current layer, including bandwidth regions of earlier layers. In order to maintain the correct coding order across layer boundaries, if a coefficient has been coded at the current bitplane depth in previous layers then it is not re-coded within the current layer. For example, the refinement stage at step s1709 only outputs refinement bits for significant coefficients identified in earlier bitplanes and not refined at the current bitplane level within previous layers.

Referring again to FIG. 15, the layered bitplane decoding unit 1502 decodes a set of coefficients in each bitplane of each layer that is restricted to coefficient frequencies within the bandwidth limit of the respective layer. The operation of a layered bitplane decoding process 1502 according to the fifth embodiment of the invention (not shown) mirrors the encoding algorithm shown in FIG. 17, and is similar to the fixed-bandwidth bitplane decoding process of the second embodiment shown in FIG. 10 except that bitplane list scans are embedded within an outer layer loop in order to decode a layered datastream structure.

Referring once again to FIG. 14, the layered bitplane encoding unit 1405 codes a set of coefficients in each bitplane of each layer that is restricted to coefficient frequencies within the bandwidth limit of the layer. The operation of an example layered bitplane encoding process 1405 by a sixth embodiment of the invention will now be described. This layered bitplane encoding method is similar to that of the fifth embodiment, except that an enhancement is made by extracting LIC coefficients to form a subsequence which for each bitplane significance scan within each layer is coded before the remaining LIC coefficients.

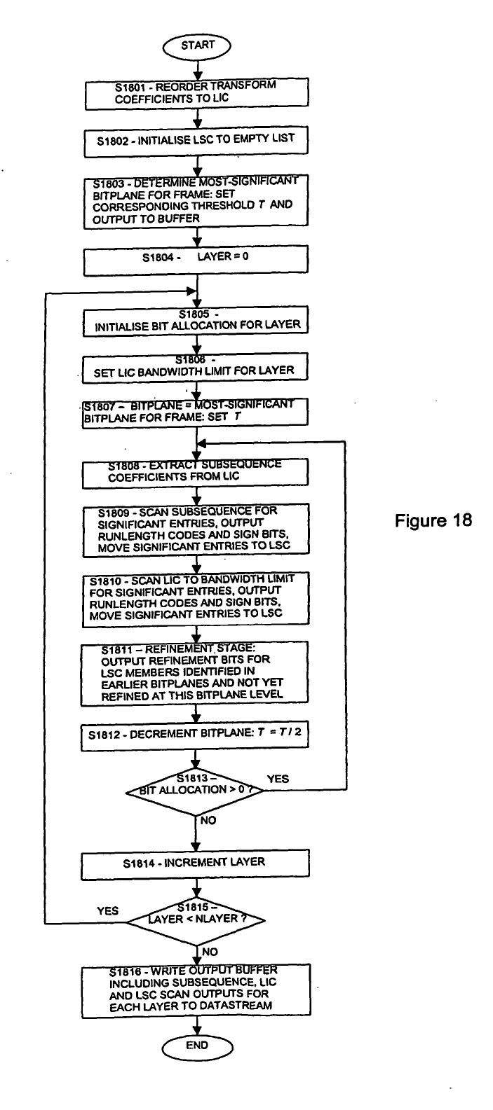

With reference to FIG. 18, the first step s1801 of the encoding algorithm reorders transform coefficients to a list of insignificant coefficients (LIC), where as before the reordering process groups together coefficients with the same frequency index within the LIC. At step s1802 a list of significant coefficients (LSC) is initialised to an empty list. The most significant bitplane for the whole frame is determined at s1803, and the corresponding threshold level T is coded and output to the output buffer. Each layer is then coded in turn, beginning with the base layer (s1804).

Each layer is associated with a bit allocation (step s1805) and bandwidth limit (s1806). Coding of each layer begins with the most significant bitplane for the frame (s1807), irrespective of whether this bitplane contains any new significant coefficients within the layer bandwidth limit, and subsequently bitplanes are coded in order of significance. For each bitplane, a significance map is coded in three stages s1808, s1809 and s1810, which collectively identify coefficients with most-significant magnitude bits in the current bitplane. Also for each bitplane, a refinement stage s1811 outputs less significant bits of significant coefficients identified in earlier bitplanes and not yet refined at this biplane level. The threshold T corresponding to the current bitplane is halved at s1812, and if bits remain from the bit allocation for the current layer (s1813), coding progresses to the next bitplane. When the bit allocation for the current layer has been used coding progresses to the next layer at s1814. When the bit allocation for the final layer has been used, coding for the current frame terminates and at step s1816 the contents of the output buffer is written to the datastream output unit 1406.

The criteria used to extract coefficients from the LIC to form a subsequence at s1808 is that the extracted coefficients should have a higher expected probability of becoming significant in the pending bitplane scan than those coefficients that remain in the LIC. Suitable contexts for selecting coefficients to form the subsequence include:
coefficients that are frequency-domain neighbours to significant coefficients with the same time index
for frames containing more than one transform block (B>1), coefficients that are time-domain neighbours to significant coefficients with the same frequency index
the significant neighbour ‘age’, or the bitplane difference between the significant neighbour MSB bitplane and the current bitplane
coefficients that have some harmonic relationship to significant coefficients.

Note that while coefficient extraction can in theory take place at any point(s) within a bitplane scan, in practice a convenient point at which to form the subsequence is at the start of each bitplane scan within each layer (as shown for s1808 in FIG. 18).

The subsequence is coded at s1809 by scanning for significant entries using runlength codes. A suitable runlength code is a fixed or adaptive Golomb code. When a significant entry is found a runlength code and sign bit are output to the output buffer and the coefficient is moved from the subsequence to the LSC. Coding the subsequence at s1809 before the remaining LIC coefficients at step s1810 results in improved coding efficiency for those frames where the final bitplane scan is only partially completed.

Following subsequence coding, the LIC is scanned for significant entries at s1810, also using runlength codes. If a fixed Golomb-Rice runlength code is used where wordlength n is fixed for all bitplanes of all frames, an optimal value for n is selected which on average results in the most compact significance map code. Alternatively n can be optimised for each frame at a certain target bitrate and sent as side information at the start of the frame, or optimised for each layer and sent as side information at the start of the layer, or optimised for each bitplane and sent as side information at the start of the bitplane. If an adaptive Golomb-Rice code is used then n is reset to a small value at the beginning of each bitplane scan within each layer (ie beginning of step s1810).

Referring once again to FIG. 15, the layered bitplane decoding unit 1502 decodes a set of coefficients in each bitplane of each layer that is restricted to coefficient frequencies within the bandwidth limit of the respective layer. The operation of a layered bitplane decoding process 1502 according to the sixth embodiment of the invention (not shown) mirrors the encoding algorithm shown in FIG. 18. Hence for each bitplane within each layer, significance map decoding comprises the steps of subsequence formation using the same context rules used in the encoder, decoding subsequence runlength codes and sign bits, and decoding LIC runlength codes and sign bits.

FIG. 19 is a block diagram of an audio transcoding apparatus of a seventh embodiment of the invention, where a coded datastream input is transcoded to a bitplane-encoded scalable datastream output. The transcoding apparatus comprises a datastream input unit 1901, a coefficient reconstruction unit 1902, a bitplane encoding unit 1903, and a scalable datastream output unit 1904.

Coded data frames representing encoded audio data are received by a datastream input unit 1901. The datastream input unit 1901 may be a storage device such as a hard disk, a RAM, and a CD-ROM, or an interface to a public telephone line, a radio line, a LAN or the like. The coded data may be of fixed-bitrate (non-scalable) format, such as provided by the MPEG-2 AAC coding standard, and as such will consist of frames of quantised and entropy-coded frequency-domain coefficients. The datastream input unit 1901 also receives coded side information such as banded weight data for each frame.

Quantised and entropy-coded data for each frame is input to the coefficient reconstruction unit 1902, where frequency-domain coefficients are reconstructed from their coded representations. Reconstructed coefficients are then input to the bitplane encoding unit 1903, where coefficient bits of equal significance are grouped together into bitplanes, and each bitplane coded in order of significance. The bitplane encoding unit 1903 can use any of the bitplane encoding algorithms described for previous embodiments, and can be of fixed-bandwidth or layered design.

The final stage of the transcoding process shown in FIG. 19 is to transmit to a memory or an external apparatus the bitplane encoded data output from the bitplane encoding unit 1903, and also side information such as banded weight data, by means of a datastream output unit 1904. The datastream output unit 1904 may be a storage device such as a hard disk, a RAM, and a CD-ROM, or an interface to a public telephone line, a radio line, a LAN or the like.

The apparatus shown in FIG. 19 is useful for converting fixed-bitrate coded audio data to a scalable datastream format. Since at all stages coded data is processed in the frequency domain and at no point transformed to the time domain, such an apparatus can be computationally efficient.

FIG. 20 is a block diagram of an audio transcoding apparatus also according to the seventh embodiment of the invention, where a bitplane-encoded scalable datastream input is transcoded to a datastream output. The transcoding apparatus comprises a scalable datastream input unit 2001, a bitplane decoding unit 2002, a coefficient quantisation and coding unit 2003, and a datastream output unit 2004.

Coded data frames representing bitplane-encoded audio data are received by a datastream input unit 2001. The datastream input unit 2001 may be a storage device such as a hard disk, a RAM, and a CD-ROM, or an interface to a public telephone line, a radio line, a LAN or the like. The datastream input unit 2001 also receives coded side information such as banded weight data for each frame.

Coded data is input to a bitplane decoding unit 2002 that reconstructs frequency-domain coefficients in bitplane order. The bitplane decoding unit 2002 can use any of the bitplane decoding algorithms described for previous embodiments of the invention, and can be of fixed-bandwidth or layered design, depending on the format of the datastream received by the datastream input unit 2001.

Reconstructed frequency-domain coefficients are then requantised and entropy coded in the coefficient quantisation and coding unit 2003, according to the format required by the datastream output unit 2004. The output data may be of fixed-bitrate (non-scalable) format, such as provided by the MPEG-2 AAC coding standard.

The final stage of the transcoding process shown in FIG. 20 is to transmit to a memory or an external apparatus the coded data output from the coefficient quantisation and coding unit 2003, and also side information such as banded weight data, by means of a datastream output unit 2004. The datastream output unit 2004 may be a storage device such as a hard disk, a RAM, and a CD-ROM, or an interface to a public telephone line, a radio line, a LAN or the like.

The apparatus shown in FIG. 20 is useful for converting bitplane-encoded scalable audio data to a fixed-bitrate datastream format. Since at all stages coded data is processed in the frequency domain and at no point transformed to the time domain, such an apparatus can be computationally efficient.

The previous embodiments have described single-channel coding cases. However, in general audio signals possess more than one channel, and of particular interest is the two-channel stereo case. The coding techniques described above for single-channel signals can also be used to code stereo and other multi-channel signals.

A common method of representing stereo signals for audio coding is as m-s channel pairs, where the ‘mid’ signal is obtained by summing left and right stereo channels, and the ‘side’ signal is obtained by forming the difference between the left and right channels. Sum and difference operations can be performed either in the time or frequency domains. M-S signals can be coded using the fixed-bandwidth bitplane coding methods described above by initially coding the mid and side signals independently, but outputting coded bitplanes of equal significance to a datastream in interleaved m-s order. Because the mid signal is usually larger than the side signal, the first few bitplanes of an interleaved output will often contain mid signal information only.

An alternative arrangement may be preferred when layered coding is used. For 2-channel layered coding the base (first) layer may be coded as a single-channel signal for the best subjective performance at lower bitrates—hence the base layer consists of a bitplane-coded mid signal only. The second layer then adds stereo coding to the same bandwidth as the first layer, hence the second layer consists of a bitplane-coded side signal only. Subsequent layers will consist of interleaved mid-side bitplanes each corresponding to a new coding bandwidth limit.

In general, this application is intended to cover any adaptations or variations of the present invention; in particular it will be realised that elements described in the embodiments may be replaced with equivalent elements fulfilling the same function. Although various features have been described in specific combinations it should be understood that these combinations are not limiting, and that the invention may be embodied in other combinations of features, as defined by the accompanying claims.

1. A method for encoding audio signals to a datastream, comprising the steps of:
reordering frequency-domain coefficients representing the audio signal to a coefficient list, where the list order preserves the frequency order of coefficients and groups together coefficients with the same frequency index;
quantising the coefficients;
arranging quantised coefficient bits of equal significance together into bitplanes, and coding groups of one or more bitplanes in order of significance beginning with the most significant group, the coding comprising coding the location of newly-significant coefficients with most-significant magnitude bit (MSB) positions within the current group, by runlength coding positions of coefficient list entries whose magnitudes equal or exceed a predetermined threshold level corresponding to the current group.

2. A method according to claim 1, wherein the audio signal is divided into frames, each frame containing one or more blocks, a plurality of frequency-domain coefficients being provided for each block, and wherein reordering comprises, for each frame, grouping together frequency-domain coefficients with the same frequency index.

3. A method according to claim 1, wherein coefficient list runlength coding is performed using Golomb codes including a Golomb parameter.

4. A method according to claim 3, wherein the Golomb parameter is adaptive, and side information representing the parameter is output to the datastream.

5. A method according to claim 3, wherein the Golomb parameter is adaptive within a bitplane or group of bitplanes, according to previously coded data.

6. A method according to claim 5, wherein the Golomb parameter is reset at the beginning of each bitplane or group of bitplanes.

7. A method according to claim 1, wherein coefficient list runlength coding is performed using reversible variable length codes.

8. A method according to claim 1, wherein coding bitplanes or bitplane groups includes coding the signs of newly significant coefficients.

9. A method according to claim 1, wherein coding bitplanes or bitplane groups includes removing newly significant coefficients from the coefficient list.

10. A method according to claim 9, wherein newly-significant coefficient list entries are moved to a list of significant coefficients (LSC), and less-significant magnitude bit information for significant coefficients identified in earlier bitplanes or bitplane groups is coded by coding corresponding LSC entries with respect to the current threshold level.

11. A method according to claim 1, wherein prior to quantisation, frequency-domain coefficients are weighted in a frequency-dependent manner.

12. A method according to claim 11, where weighting is performed with a set of banded weight values which are coded and output as side information to the datastream.

13. A method according to claim 1, wherein coefficient list runlength coding is completed following the final significant list entry by coding repeated symbols until the end of the coefficient list is passed.

14. A method according to claim 1, where coding of one or more bitplanes or bitplane groups further includes:
forming a subsequence from coefficient list entries, where the subsequence selection criteria are based on increased expected probability of significance within the current bitplane or bitplane group;
locating newly-significant subsequence entries using runlength codes before locating newly-significant coefficients amongst the remaining coefficient list entries.

15. A method according to claim 14, where a new subsequence is formed at the beginning of coding a bitplane or bitplane group.

16. A method according to claim 14, wherein the contexts for selecting coefficient list entries to form a subsequence include any of the following:
spectral proximity to significant coefficients with the same time index;
temporal proximity to significant coefficients with the same frequency index;
the bitplane differences between most-significant bit (MSB) bitplanes of significant neighbour coefficients and the current bitplane;
spectral harmonic relationships with significant coefficients.

17. A method according to claim 1, wherein the datastream comprises a base layer and a number of enhancement layers each having predetermined coefficient bandwidth limits, characterised in that coefficients corresponding to each layer are quantised and coded until a bit allocation is reached, prior to coding the next layer, the base layer being coded first.

18. A method according to claim 17, wherein coding of enhancement layers includes coding quantised coefficient data contained within previous layer bandwidth limits but not coded in said previous layers.

19. A method according to claim 17, wherein runlength codes are preceded by a flag to indicate whether the coefficient list contains any newly-significant coefficients within the bandwidth limit of the current layer.

20. A method according to claim 19, where the flag is a single bit.

21. A method for decoding a datastream representing an audio signal, comprising the steps of:
initialising entries in a coefficient list to zero;
decoding bitplane data from the datastream in order of significance beginning with the most significant bitplane or bitplane group, by decoding runlength codes to locate newly-significant coefficient list entries which have most-significant magnitude bit (MSB) positions within the current bitplane or bitplane group, setting magnitudes of said newly-significant coefficient list entries to a predetermined threshold level corresponding to the current bitplane or bitplane group, and removing said newly-significant entries from the coefficient list;
reordering significant coefficients removed from the coefficient list to a set of frequency-domain output coefficients.

22. A method according to claim 21, wherein the audio signal is divided into frames, each frame containing one or more blocks, a plurality of frequency-domain coefficients being provided for each block, and wherein reordering comprises grouping together coefficients corresponding to the same block, preserving the frequency order within each block.

23. A method according to claim 21, wherein decoding includes decoding the signs of newly-significant coefficients.

24. A method according to claim 21, wherein newly-significant coefficient list entries are moved to a list of significant coefficients (LSC), and less-significant magnitude bit information for significant coefficients identified in earlier bitplanes is decoded by decoding LSC refinement data with respect to the current threshold level.

25. A method according to claim 21, wherein the datastream comprises a base layer and a number of enhancement layers, each having predetermined coefficient bandwidth limits, characterised in that data corresponding to each layer are decoded until a bit allocation is reached, prior to decoding the next layer, the base layer being decoded first.

26. A method according to claim 25, wherein decoding of enhancement layers includes decoding data contained within previous layer bandwidth limits but not decoded in said previous layers.

27. A method according to claim 21, wherein the datastream is a layered datastream, and further comprising the step of transforming reconstructed output coefficients to a time-domain output signal and lowpass filtering the time-domain output signal, where the lowpass filter cutoff frequency is dependent on the coefficient bandwidth limit of the last layer decoded.

28. A method for decoding audio signals from a layered datastream, each layer having an associated bandwidth, comprising the steps of:
decoding the datastream to produce output coefficients;
transforming reconstructed output coefficients to a time-domain output signal; and
lowpass filtering the time-domain output signal, where the lowpass filter cutoff frequency is dependent on the bandwidth of the last layer decoded.

29. A method according to claim 28, where the lowpass filter cutoff frequency is adapted in time.

30. A method according to claim 28, where decoding of data corresponding to a subsequent layer includes decoding data for coefficients contained within the bandwidth limits of previous layers.

31. (canceled)

32. Apparatus for encoding audio signals to a datastream, the apparatus comprising:
reordering means for reordering frequency-domain coefficients representing the audio signal to a coefficient list, where the list order preserves the frequency order of coefficients and groups together coefficients with the same frequency index;
means for quantising the coefficients; and
means for arranging quantised coefficient bits of equal significance into bitplanes and coding groups of one or more bitplanes in order of significance beginning with the most significant group, the coding comprising coding the location of newly-significant coefficients with most-significant magnitude bit (MSB) positions within the current group, by runlength coding positions of coefficient list entries whose magnitudes equal or exceed a predetermined threshold level corresponding to the current group.

33. An audio encoder comprising:
a transform stage for converting audio samples into frequency-domain coefficients, with the capability of utilising multiple transform blocks in each frame of audio samples;
a register adapted to reorder the coefficients by interleaving sets of coefficients so as to group together coefficients with the same frequency index;
a quantiser; and
a bitplane coder, adapted to arrange bits of quantised coefficients of equal significance into bitplanes, and code groups of one or more bitplanes in order of significance, beginning with the most significant group, wherein the coding is performed by runlength coding the positions of coefficients having most significant bits (MSBs) within the current group to produce an output datastream.

34. An audio decoder comprising:
a bitplane decoder adapted to receive a datastream and, for each bitplane or group of bitplanes received, to decode runlength codes to locate coefficients with most significant bit (MSB) positions within the current bitplane or bitplane group, and to set magnitudes of said coefficients to a predetermined threshold level corresponding to the current bitplane or bitplane group;
a register adapted to reorder coefficient values from the decoder to a set of frequency-domain output coefficients; and
a transform stage for converting frequency-domain coefficients into audio samples.

35. Apparatus for decoding audio signals from a layered datastream, each layer having an associated bandwidth, comprising:
means for decoding the datastream to produce output coefficients;
means for transforming reconstructed output coefficients to a time-domain output signal; and
an adaptive filter for lowpass filtering the time-domain output signal, where the lowpass filter cutoff frequency is dependent on the bandwidth of the last layer decoded.

36. A method for use in the encoding of audio signals to a layered data stream using run length bitplane coding, wherein the location of newly-significant coefficients with most-significant magnitude bit (MSB) positions within the current bitplane are runlength coded, characterised in that runlength codes are preceded by a flag to indicate whether the bitplane contains any newly-significant coefficients within the bandwidth limit of the current layer.
